(19) United States
(12) Patent Application Publication
(10) Pub. No.: US 2025/0255155 A1
(43) Pub. Date: Aug. 7, 2025

(54) DISPLAY DEVICE AND METHOD OF MANUFACTURING THE SAME

(71) Applicant: Samsung Display Co., LTD., Yongin-si (KR)

(72) Inventors: Dong Hee SHIN, Yongin-si (KR); Sun Kwun SON, Yongin-si (KR); Na Hyeon CHA, Yongin-si (KR); Sang Yong NO, Yongin-si (KR)

(73) Assignee: Samsung Display Co., LTD., Yongin-si (KR)

(21) Appl. No.: 18/797,992

(22) Filed: Aug. 8, 2024

(30) Foreign Application Priority Data
Feb. 7, 2024 (KR) 10-2024-0019058

(51) Int. Cl. H10K 59/80

(52) U.S. Cl. CPC H10K 59/877

(57) ABSTRACT

A display device including a first pixel adjacent to a second pixel, the display device may include a substrate, a pixel circuit layer disposed on the substrate, and a display element layer including a plurality of anode electrodes disposed on the pixel circuit layer, wherein the plurality of anode electrodes include a first anode electrode corresponding to the first pixel and a second anode electrode corresponding to the second pixel. The pixel circuit layer may include a via layer facing the display element layer and including a first slit pattern overlapping the first anode electrode and a second slit pattern overlapping the second anode electrode, the second slit pattern may be different from the first slit pattern in at least one of a shape, a size, and a position.

### CROSS-REFERENCE TO RELATED APPLICATION(S)

This application claims priority under 35 U.S.C. § 119 from Korean Patent Application No. 10-2024-0019058 filed on Feb. 7, 2024 in the Korean Intellectual Property Office, the entire contents of which are incorporated herein by reference.

### BACKGROUND

### 1. Technical Field

Embodiments of the disclosure relate to a display device and a method of manufacturing the same.

### 2. Description of the Related Art

As information technology develops, importance of a display device, which is a connection medium between a user and information, is emerging. In response to this, a use of the display device such as a liquid crystal display device and an organic light emitting display device is increasing.

### SUMMARY

An object of the disclosure is to provide a display device that improves user visibility by improving a diffraction pattern.

Another object of the disclosure is to provide a method of manufacturing a display device with improved user visibility through diffraction pattern improvement.

However, an object of the disclosure is not limited to the above-described objects, and may be expanded variously without departing from the spirit and scope of the disclosure.

In order to achieve an object of the disclosure, according to embodiments of the disclosure, a display device may include a first pixel adjacent to a second pixel, a pixel circuit layer disposed on a substrate, and a display element layer including a plurality of anode electrodes disposed on the pixel circuit layer, wherein the plurality of anode electrodes include a first anode electrode corresponding to the first pixel and a second anode electrode corresponding to the second pixel. The pixel circuit layer may include a via layer facing the display element layer, an upper surface of the via layer may include a plurality of slit patterns respectively overlapping the plurality of anode electrodes, and the plurality of slit patterns may be adjacent to the display element layer, the plurality of slit patterns may include a first slit pattern overlapping the first anode electrode and a second slit pattern overlapping the second anode electrode, and the first slit pattern and the second slit pattern may be different from each other in at least one of a shape, a size, and a position, and a portion of the first and second anode electrodes overlapping the first and second slit patterns may have a shape corresponding to the first and second slit patterns.

In an embodiment, the first pixel may include a (1-1)-th sub-pixel and a (1-2)-th sub-pixel adjacent to the (1-1)-th sub-pixel, the second pixel may include a (2-1)-th sub-pixel and a (2-2)-th sub-pixel adjacent to the (2-1)-th sub-pixel, the first anode electrode may include a (1-1)-th sub anode electrode corresponding to the (1-1)-th sub-pixel and a (1-2)-th sub anode electrode corresponding to the (1-2)-th sub-pixel, the second anode electrode may include a (2-1)-th sub anode electrode corresponding to the (2-1)-th sub-pixel and a (2-2)-th sub anode electrode corresponding to the (2-2)-th sub-pixel, the first slit pattern may include a (1-1)-th sub slit pattern corresponding to the (1-1)-th sub anode electrode and a (1-2)-th sub slit pattern corresponding to the (1-2)-th sub anode electrode, and the (1-1)-th sub slit pattern and the (1-2)-th sub slit pattern may have substantially a same shape, the second slit pattern may include a (2-1)-th sub slit pattern corresponding to the (2-1)-th sub anode electrode and a (2-2)-th sub slit pattern corresponding to the (2-2)-th sub anode electrode, and the (2-1)-th sub slit pattern and the (2-2)-th sub slit pattern may have substantially a same shape.

In an embodiment, the (1-1)-th sub slit pattern and the (1-2)-th sub slit pattern may have different sizes.

In an embodiment, the (2-1)-th sub slit pattern and the (2-2)-th sub slit pattern may have different sizes.

In an embodiment, each of the first slit pattern and the second slit pattern may have an elliptical shape.

In an embodiment, a first center of the first slit pattern in the first pixel and a second center of the second slit pattern in the second pixel may be disposed at substantially a same position.

In an embodiment, the first slit pattern may include a (1-1)-th trench and a (1-2)-th trench of a closed loop shape, which may be sequentially formed spaced apart from each other in a radial direction with respect to the first center, and the second slit pattern may include a (2-1)-th trench and a (2-2)-th trench of a closed loop shape, which may be sequentially formed spaced apart from each other in a radial direction with respect to the second center.

In an embodiment, an area of a portion of the first slit pattern surrounded by the (1-1)-th trench may be different from an area of the second slit pattern surrounded by the (2-1)-th trench.

In an embodiment, each of the (1-1)-th trench and the (1-2)-th trench may have a width of about 1.5 μm or less in the radial direction with respect to the first center, and each of the (2-1)-th trench and the (2-2)-th trench may have a width of about 1.5 μm or less in the radial direction with respect to the second center.

In an embodiment, the (1-1)-th trench and the (1-2)-th trench may be spaced apart from each other by a distance of about 1.5 μm or less in the radial direction with respect to the first center, and the (2-1)-th trench and the (2-2)-th trench may be spaced apart from each other by a distance of about 1.5 μm or less in the radial direction with respect to the second center.

In an embodiment, a farthest separation distance between the first center and the (1-1)-th trench may be defined as a first major radius, a farthest separation distance between the second center and the (2-1)-th trench may be defined as a second major radius, and a virtual line extending in the first major radius and a virtual line extending in the second major radius may intersect each other.

In an embodiment, a closest separation distance between the first center and the (1-1)-th trench may be defined as a first minor radius, a closest separation distance between the second center and the (2-1)-th trench may be defined as a second minor radius, the first major radius and the first minor radius may be determined according to Formula 1, the second major radius and the second minor radius may be determined according to Formula 2, and

$${( 1 - {( RB 1 )}^{2} / {( RA 1 )}^{2} )}^{1 / 2} \leq 0.7 \qquad [ Formula 1 ]$$

$${( 1 - {( RB 2 )}^{2} / {( RA 2 )}^{2} )}^{1 / 2} \leq 0.7 \qquad [ Formula 2 ]$$

the RA1, RB1, RA2, and RB2 may represent the first major radius, the first minor radius, the second major radius, and the second minor radius, respectively.

In an embodiment, the first pixel may further include a (1-3)-th sub-pixel adjacent to the (1-1)-th sub-pixel and the (1-2)-th sub-pixel, the second pixel may further include a (2-3)-th sub-pixel adjacent to the (2-1)-th sub-pixel and the (2-2)-th sub-pixel, the first anode electrode may further include a plurality of (1-3)-th sub anode electrodes corresponding to the (1-3)-th sub-pixel, the second anode electrode may further include a plurality of (2-3)-th sub anode electrodes corresponding to the (2-3)-th sub-pixel, the first slit pattern may further include a plurality of (1-3)-th sub slit patterns overlapping the (1-3)-th sub anode electrode, and the second slit pattern may further include a plurality of (2-3)-th sub slit patterns overlapping the (2-3)-th sub anode electrode.

In an embodiment, a position in the (1-3)-th sub-pixel of at least one of first centers of the plurality of (1-3)-th sub slit patterns in the plurality of (1-3)-th sub anodes may be different from a position in the (2-3)-th sub-pixel of at least one of second centers of the plurality of (2-3)-th sub slit patterns in the plurality of (2-3)-th sub anodes.

In an embodiment, at least one of the (1-1)-th sub slit pattern, the (1-2)-th sub slit pattern, and the (1-3)-th sub slit pattern may have a size different from another of the (1-1)-th sub slit pattern, the (1-2)-th sub slit pattern, and the (1-3)-th sub slit pattern.

In an embodiment, at least one of the (2-1)-th sub slit pattern, the (2-2)-th sub slit pattern, and the (2-3)-th sub slit pattern may have a size different from another of the (2-1)-th sub slit pattern, the (2-2)-th sub slit pattern, and the (2-3)-th sub slit pattern.

In order to achieve an object of the disclosure, according to embodiments of the disclosure, a method of manufacturing a display device may include providing a first pixel adjacent to a second pixel, forming a pixel circuit layer on a substrate, forming a via layer on the pixel circuit layer, the via layer may include a first portion corresponding to the first pixel and a second portion corresponding to a second pixel, forming a plurality of slit patterns in the via layer, the plurality of slit patterns may include a first slit pattern corresponding to the first portion of the via layer and the second portion corresponding to the second portion of the via layer, and forming a plurality of anode electrodes including a first anode electrode overlapping the first slit pattern and a second anode electrode overlapping the second slit pattern, and the first slit pattern and the second slit pattern may be different in at least one of a shape, a size, and a position.

In an embodiment, the forming of the plurality of slit patterns may include irradiating light to the first and second portions of the via layer using a mask where an opening corresponding to a shape of the first slit pattern and the second slit pattern may be formed, and forming the first slit pattern and the second slit pattern through exposure and development processes.

In an embodiment, each of the first slit pattern and the second slit pattern may be formed in an elliptical shape, and positions of the first slit pattern and the second slit pattern may be different from each other.

In an embodiment, a portion of the first and second anode electrodes overlapping the first and second slit patterns may have a shape corresponding to the first and second slit patterns.

According to embodiments of the disclosure, by forming a structure of anode electrodes capable of emitting light of the same wavelength in different directions from each of neighboring sub-pixels, diffraction interference between the light emitted from the neighboring sub-pixels may be minimized, and thus a display device and a method of manufacturing the same that may improve user visibility may be provided.

However, an effect of the disclosure is not limited to the effect described above, and may be expanded variously without departing from the spirit and scope of the disclosure.

### BRIEF DESCRIPTION OF THE DRAWINGS

The above and other features of the disclosure will become more apparent by describing in further detail embodiments thereof with reference to the accompanying drawings, in which:

FIG. 1 is a perspective view of a display device according to an embodiment of the disclosure;

FIG. 2 is a side view of a display device according to an embodiment of the disclosure;

FIG. 3 is a plan view of a display panel according to an embodiment of the disclosure;

FIG. 4 is a plan view illustrating an embodiment of two pixels adjacent to each other among pixels shown in FIG. 3;

FIG. 5A is a schematic cross-sectional view taken along line I-I′ of FIG. 4;

FIG. 5B is an enlarged schematic cross-sectional view of area A of FIG. 5A;

FIG. 6 is a plan view illustrating an embodiment of a first slit pattern and a second slit pattern shown in FIG. 4;

FIG. 7 is a plan view illustrating an embodiment of a (1-1)-th slit pattern and a (2-1)-th slit pattern;

FIG. 8 is a plan view illustrating an embodiment of the two pixels adjacent to each other among the pixels of FIG. 3;

FIG. 9 is a plan view illustrating still an embodiment of the first slit pattern and the second slit pattern shown in FIG. 8;

FIG. 10 is a schematic cross-sectional view illustrating forming a pixel circuit layer on a substrate;

FIG. 11 is a schematic cross-sectional view illustrating forming a first photosensitive material layer on the pixel circuit layer;

FIG. 12 is a schematic cross-sectional view illustrating a state in which a first pattern mask is disposed on the first photosensitive material layer;

FIG. 13 is a schematic cross-sectional view illustrating irradiating light toward the first pattern mask and the first photosensitive material layer;

FIG. 14 is a schematic cross-sectional view illustrating developing a partial area of an exposed first photosensitive material layer;

FIG. 15 is a schematic cross-sectional view illustrating forming an anode electrode on a via layer;

FIG. 16 is a schematic cross-sectional view illustrating forming a second photosensitive material layer on the via layer and an anode electrode;

FIG. 17 is a schematic cross-sectional view illustrating a state in which a second pattern mask is disposed on the second photosensitive material layer;

FIG. 18 is a schematic cross-sectional view illustrating irradiating light toward the second pattern mask and the second photosensitive material layer;

FIG. 19 is a schematic cross-sectional view illustrating forming a pixel defining layer by developing a partial area of an exposed second photosensitive material layer;

FIG. 20 is a schematic cross-sectional view illustrating forming a light emitting element layer and a cathode electrode on an anode electrode exposed by an opening; and

FIG. 21 is a schematic cross-sectional view illustrating forming a thin film encapsulation layer and a window on the cathode electrode.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

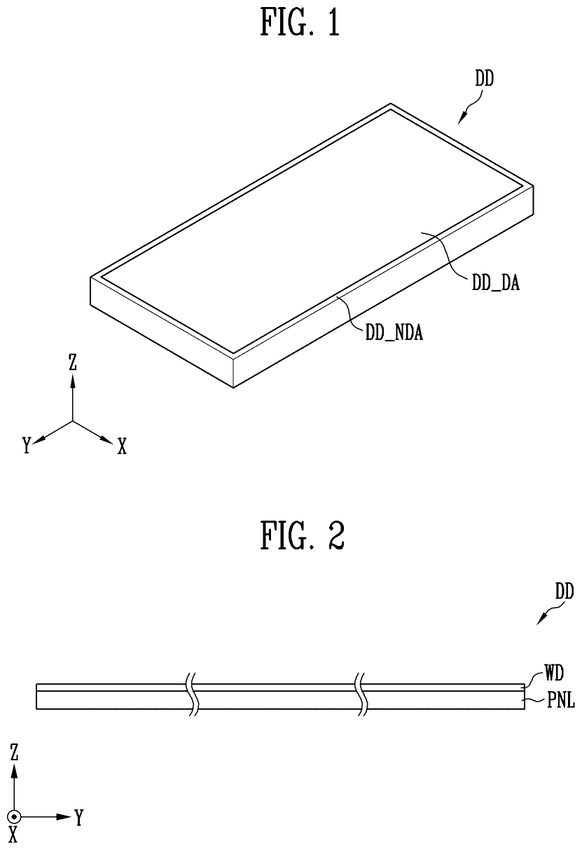

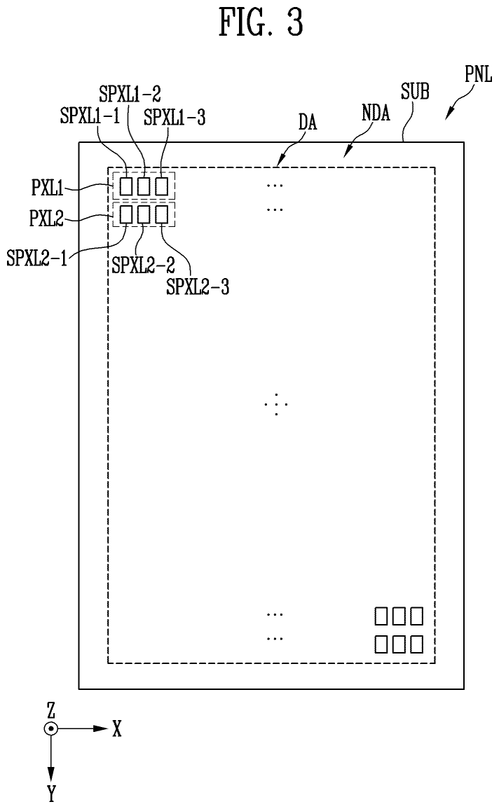

FIG. 1 is a perspective view of a display device according to an embodiment of the disclosure, FIG. 2 is a side view of a display device according to an embodiment of the disclosure, and FIG. 3 is a plan view of a display panel according to an embodiment of the disclosure.

Referring to FIGS. 1 to 3, the display device DD may include a display panel PNL and a window WD.

The display device DD may include a display area DD_DA that displays an image and a non-display area DD_NDA that does not display an image. The non-display area DD_NDA may be provided on at least one side of the display area DD_DA. As an example, the non-display area DD_NDA may be provided to surround the display area DD_DA.

The display device DD may be provided in a rectangular plate shape having an angled corner as shown in FIGS. 1 to 3, but according to embodiments, the corner of the display device DD may have a curved shape. However, the disclosure is not necessarily limited thereto, and the display device DD may be implemented in various shapes.

The display device DD may be applied to an electronic device to which a display surface may be applied to at least one surface, such as a smartphone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, or a wearable display device.

Referring to FIG. 3, the display panel PNL and a substrate SUB for forming the same may include a display area DA for displaying an image and a non-display area NDA excluding the display area DA. The display area DA may configure a screen on which an image may be displayed, and the non-display area NDA may be a remaining area excluding the display area DA.

For convenience of description, a structure of the display panel PNL is briefly shown in FIG. 3 based on the display area DA. However, according to embodiments, at least one driving circuit part (for example, at least one of a scan driver and a data driver), lines, and/or pads may be further disposed on the display panel PNL.

A first pixel PXL1 and a second pixel PXL2 may be disposed in the display area DA. The first pixel PXL1 may include a (1-1)-th sub-pixel SPXL1-1, a (1-2)-th sub-pixel SPXL1-2, and a (1-3)-th sub-pixel SPXL1-3. The second pixel PXL2 may include a (2-1)-th sub-pixel SPXL2-1, a (2-2)-th sub-pixel SPXL2-2, and a (2-3)-th sub-pixel SPXL2-3.

Although not shown in detail in the drawings, the first pixel PXL1 and the second pixel PXL2 may be repeatedly arranged on a plane formed by an X-axis and a Y-axis in the display area DA. Each of the first pixel PXL1 and the second pixel PXL2 may be shown to include three sub-pixels, but is not necessarily limited thereto. According to an embodiment, each of the first pixel PXL1 and the second pixel PXL2 may include multiple sub-pixels, such as two or four.

In FIG. 3, each of the sub-pixels SPXL1-1, SPXL1-2, SPXL1-3, SPXL2-1, SPXL2-2, and SPXL2-3 may be shown to have a quadrangular shape when viewed in a Z-axis direction (or in a plan view) and has the same size as each other, but embodiments are not limited thereto. For example, each of the sub-pixels may be transformed to have various shapes, such as a polygonal shape with a rounded corner, a circular shape, or an elliptical shape, as well as a quadrangular shape.

Hereinafter, in case that at least one sub-pixel is arbitrary referred to or two or more types of sub-pixels are comprehensively referred to among individual sub-pixels such as the (1-1)-th sub-pixel SPXL1-1, the (1-2)-th sub-pixel SPXL1-2, the (1-3)-th sub-pixel SPXL1-3, the (2-1)-th sub-pixel SPXL2-1, the (2-2)-th sub-pixel SPXL2-2, and the (2-3)-th sub-pixel SPXL2-3, the at least one sub-pixel or the two or more types of sub-pixels is or are referred to as “pixel PXL” or “pixels PXL”.

The pixels PXL may be arranged regularly according to a stripe or PENTILE™ arrangement structure, or the like. However, the arrangement structure of the pixels PXL is not limited thereto, and the pixels PXL may be arranged in the display area DA in various structures and/or methods.

According to an embodiment, two or more types of pixels PXL that emit light of different colors may be disposed in the display area DA. For example, in the display area DA, the (1-1)-th sub-pixels SPXL1-1 and/or the (2-1)-th sub-pixels SPXL2-1 that emit light of a first color, the (1-2)-th sub-pixels SPXL1-2 and/or the (2-2)-th sub-pixels SPXL2-2 that emit light of a second color, and the (1-3)-th sub-pixels SPXL1-3 and/or the (2-3)-th sub-pixels SPXL2-3 that emit light of a third color may be arranged.

At least two sub-pixels disposed adjacent to each other among the (1-1)-th to (1-3)-th sub-pixels SPXL1-1, SPXL1-2, and SPXL1-3 or at least two sub-pixels disposed adjacent to each other among the (2-1)-th to (2-3)-th sub-pixels SPXL2-1, SPXL2-2, and SPXL2-3 may configure the first pixel PXL1 or the second pixel PXL2 capable of emitting light of various colors.

For example, the (1-1)-th sub-pixel SPXL1-1 and/or the (2-1)-th sub-pixel SPXL2-1 may be a red pixel that emits red light, the (1-2)-th sub-pixel SPXL1-1 and/or the (2-2)-th sub-pixel SPXL2-2 may be a green pixel that emits green light, and the (1-3)-th sub-pixel SPXL1-3 and/or the (2-3)-th sub-pixel SPXL2-3 may be a blue pixel that emits blue light, but the disclosure is not limited thereto.

In FIG. 3, a case where the first pixel PXL1 includes one (1-1)-th sub-pixel SPXL1-1, one (1-2)-th sub-pixel SPXL1-2, and one (1-3)-th sub-pixel SPXL1-3 is illustrated, but the disclosure is not necessarily limited thereto. According to embodiments, the first pixel PXL1 may include one (1-1)-th sub-pixel SPXL1-1, one (1-2)-th sub-pixel SPXL1-2, and two (1-3)-th sub-pixels SPXL1-3.

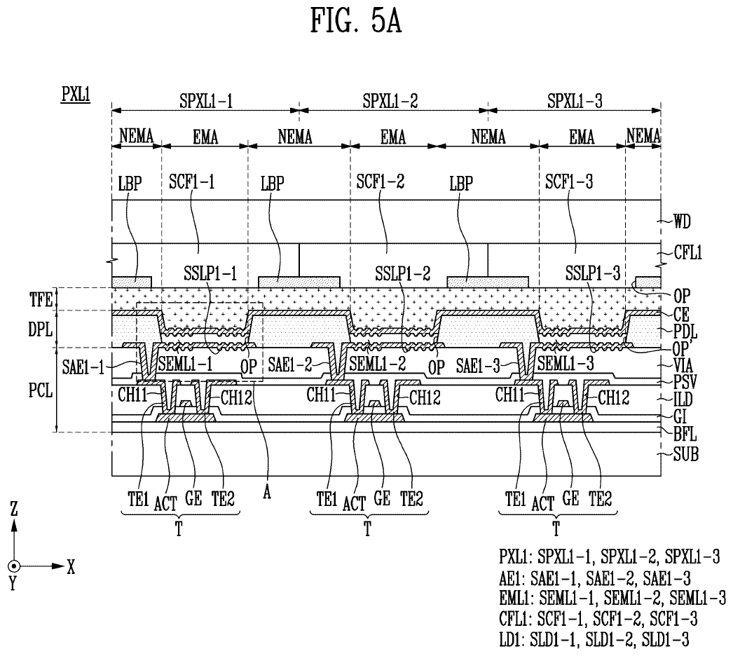

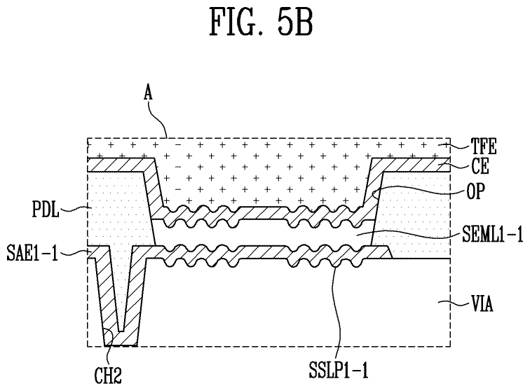

The (1-1)-th sub-pixel SPXL1-1, the (1-2)-th sub-pixel SPXL1-2, and the (1-3)-th sub-pixel may respectively include a (1-1)-th sub light emitting element SLD1-1 of FIG. 5A, a (1-2)-th sub light emitting element SLD1-2 of FIG. 5A, and a (1-3)-th sub light emitting element SLD1-3 of FIG. 5A as a light source to emit the light of the first color, the light of the second color, and the light of the third color, respectively. However, a color of light emitted by each pixel PXL may be variously changed.

A window WD for protecting an exposure surface of the display panel PNL may be provided on the display panel PNL. The window WD may protect the display panel PNL from external shock and may provide an input surface and/or a display surface to a user. The window WD may be coupled to the display panel PNL using an optically transparent cohesive (or adhesive) member (not shown).

The window WD may have a multilayer structure selected from a glass substrate, a plastic film, and a plastic substrate. The multilayer structure may be formed through a continuous process or an adhesion process using an adhesive layer. The entire of a portion of the window WD may have flexibility.

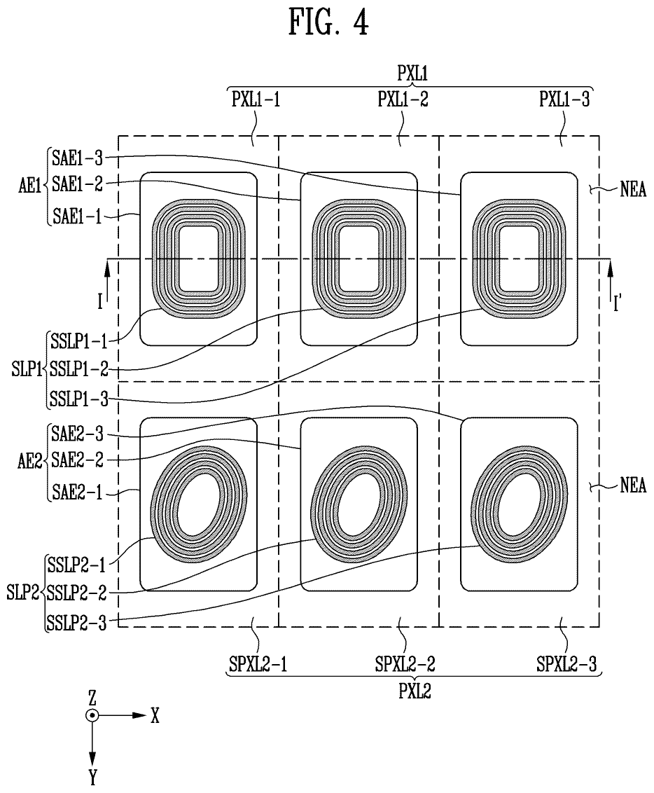

FIG. 4 is a plan view illustrating an embodiment of one of the pixels of FIG. 3, FIG. 5A is a schematic cross-sectional view taken along line I-I′ of FIG. 4, and FIG. 5B is an enlarged schematic cross-sectional view of area A of FIG. 5A.

In FIG. 4, the first pixel PXL1 and the second pixel PXL2 of FIG. 3 are schematically shown for clear and concise description. The first pixel PXL1 and the second pixel PXL2 may be sequentially arranged in the Y-axis, but this is for convenience of description, and the first pixel PXL1 and the second pixel PXL2 may be arranged regularly on a plane formed by the X-axis and the Y-axis together with remaining pixels which are not shown.

The first pixel PXL1 may include the (1-1)-th sub-pixel SPXL1-1, the (1-2)-th sub-pixel SPXL1-2, and the (1-3)-th sub-pixel SPXL1-3 sequentially arranged in an X-axis direction. The second pixel PXL2 may also include the (2-1)-th sub-pixel SPXL2-1, the (2-2)-th sub-pixel SPXL2-2, and the (2-3)-th sub-pixel SPXL2-3 sequentially arranged in the X-axis direction.

The first pixel PXL1 and the second pixel PXL2 may include an emission area EMA and a non-emission area NEA around the emission area EMA. The emission area EMA may be an area where light from a light emitting element layer EML1 of FIG. 5 corresponding to each of the (1-1)-th to (1-3)-th sub-pixels SPXL1-1, SPXL1-2, and SPXL1-3, and the (2-1)-th to (2-3)-th sub-pixels SPXL2-1, SPXL2-2, and SPXL2-3 may be emitted.

The emission area EMA may be understood as each of openings OP of a pixel defining layer PDL corresponding to each of the (1-1)-th to (1-3)-th sub-pixels SPXL1-1, SPXL1-2, and SPXL1-3, and the (2-1)-th to (2-3)-th sub-pixels SPXL2-1, SPXL2-2, and SPXL2-3.

Each of the first pixel PXL1 and the second pixel PXL2 may include a pixel circuit layer PCL, a display element layer DPL, and a thin film encapsulation layer TFE sequentially disposed on the substrate SUB. Hereinafter, for convenience of description, a specific structure of the (1-1)-th to (1-3)-th sub-pixels SPXL1-1, SPXL1-2, and SPXL1-3 is described with reference to FIGS. 4, 5A and 5B together.

The substrate SUB may form a base surface. The substrate SUB may include a transparent insulating material, and thus may transmit light. The substrate SUB may be a rigid substrate or a flexible substrate. The rigid substrate may be, for example, one of a glass substrate, a quartz substrate, a glass ceramic substrate, and a crystalline glass substrate. The flexible substrate may be one of a film substrate and a plastic substrate including a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate, but is not necessarily limited thereto.

The pixel circuit layer PCL may include a pixel circuit and a sensor circuit provided on the substrate SUB.

The pixel circuit layer PCL may include a buffer layer BFL, a gate insulating layer GI, an interlayer insulating layer ILD, a passivation layer PSV, and a via layer VIA sequentially stacked on each other on the substrate SUB.

The buffer layer BFL may be an inorganic insulating layer including an inorganic material. The buffer layer BFL may include at least one of metal oxides such as silicon nitride (SiNₓ), silicon oxide (SiOₓ), silicon oxynitride (SiOₓN_{y}), and aluminum oxide (AlOₓ). The buffer layer BFL may be provided as a single layer, but may also be provided as multiple layers of at least two or more layers. In case that the buffer layer BFL is provided as the multiple layers, each layer may be formed of a same material or may be formed of different materials. The buffer layer BFL may be omitted according to a material and a process condition of the substrate SUB.

A transistor T may be disposed on the buffer layer BFL. The transistor T may include an active pattern ACT, a gate electrode GE, a first transistor electrode TE1, and a second transistor electrode TE2.

The active pattern ACT may be disposed on the buffer layer BFL. The active pattern ACT may include a polysilicon semiconductor. For example, the active pattern ACT may be formed through a low-temperature polysilicon process. However, the disclosure is not necessarily limited thereto, and the active pattern ACT may be formed of an oxide semiconductor, a metal oxide semiconductor, or the like.

Each active pattern ACT may each include a channel area, a first contact area extended to an end of the channel area, and a second contact area extended to another end of the channel area. The channel area, the first contact area, and the second contact area may be formed of a semiconductor layer that may not be doped with an impurity or may be doped with an impurity.

As an example, the first contact area and the second contact area may be formed of a semiconductor layer doped with an impurity, and the channel area may be formed of a semiconductor layer that may not be doped with an impurity. As an impurity, for example, a p-type impurity may be used, but is not limited thereto. One of the first and second contact areas may be a source area and another may be a drain area.

The gate insulating layer GI may be disposed on the active pattern ACT. The gate insulating layer GI may be an inorganic layer (or an inorganic insulating layer) including an inorganic material. The gate insulating layer GI may be provided as a single layer, but may also be provided as multiple layers of at least two or more layers.

The gate electrode GE may be disposed on the gate insulating layer GI. The gate electrode GE may overlap the channel area of the active pattern ACT. The gate electrode GE may be formed as two layer or multiple layer structure of copper (Cu), molybdenum (Mo), tungsten (W), aluminum neodymium (AlNd), titanium (Ti), aluminum (Al), silver (Ag), or a combination thereof.

The interlayer insulating layer ILD may be disposed on the gate electrode GE. The interlayer insulating layer ILD and the gate insulating layer GI may include a same material, or the interlayer insulating layer ILD may include one or more materials selected from the material exemplified as a configuration material of the gate insulating layer GI.

The first transistor electrode TE1 and the second transistor electrode TE2 may be disposed on the interlayer insulating layer ILD.

The first transistor electrode TE1 of the transistor T may contact the first contact area of the active pattern ACT through a contact hole CH11 passing through the interlayer insulating layer ILD and the gate insulating layer GI. In case that the first contact area is the source area, the first transistor electrode TE1 may be a first source electrode.

The second transistor electrode TE2 of the transistor T may contact the second contact area of another end of the active pattern ACT through a contact hole CH12 passing through the interlayer insulating layer ILD and the gate insulating layer GI. In case that the second contact area is the drain area, the second transistor electrode TE2 may be a second drain electrode.

The gate electrode GE and each of the first transistor electrode TE1 and the second transistor electrode TE2 may include a same material or each of the first transistor electrode TE1 and the second transistor electrode TE2 may include one or more materials selected from materials exemplified as a configuration material of the gate electrode GE.

The passivation layer PSV may be formed on the first transistor electrode TE1 and the second transistor electrode TE2. The passivation layer PSV (for example, a protective layer) may be an inorganic layer (or an inorganic insulating layer) including an inorganic material or an organic layer (or an organic insulating layer) including an organic material. The inorganic layer may include, for example, at least one of metal oxides such as silicon oxide (SiOₓ), silicon nitride (SiNₓ), silicon oxynitride (SiOₓN_{y}), and aluminum oxide (AlOₓ). The organic layer may include, for example, at least one of acrylic resin (polyacrylates resin), epoxy resin, phenolic resin, polyamides resin, polyimides resin, unsaturated polyesters resin, polyphenylene ethers resin, polyphenylene sulfides resin, and benzocyclobutene resin.

According to an embodiment, the passivation layer PSV and the interlayer insulating layer ILD may include a same material, but is not limited thereto. The passivation layer PSV may be provided as a single layer, but may also be provided as multiple layers of at least two or more layers.

The via layer VIA may be disposed on the passivation layer PSV. The via layer VIA and the passivation layer PSV may include a same material, or the via layer VIA may include one or more materials selected from materials exemplified as a configuration material of the passivation layer PSV. In an embodiment, the via layer VIA may be an organic layer formed of an organic material.

The display element layer DPL may be disposed on the pixel circuit layer PCL.

The display element layer DPL may include multiple anode electrodes AE disposed on the pixel circuit layer PCL, and multiple light emitting element layers EML and a cathode electrode CE formed on each of the anode electrodes AE.

The anode electrodes AE may include a first anode electrode AE1 corresponding to the first pixel PXL1 and a second anode electrode AE2 corresponding to the second pixel PXL2.

The first anode electrode AE1 includes a (1-1)-th sub anode electrode SAE1-1 corresponding to the (1-1)-th sub-pixel SPXL1-1, a (1-2)-th sub anode electrode SAE1-2 corresponding to the (1-2)-th sub-pixel SPXL1-2, and a (1-3)-th sub anode electrode SAE1-3 corresponding to the (1-3)-th sub-pixel SPXL1-3.

Similarly, the second anode electrode AE2 includes a (2-1)-th sub anode electrode SAE2-1 corresponding to the (2-1)-th sub-pixel SPXL2-1, a (2-2)-th sub anode electrode SAE2-2 corresponding to the (2-2)-th sub-pixel SPXL2-2, and a (2-3)-th sub anode electrode SAE2-3 corresponding to the (2-3)-th sub-pixel SPXL2-3.

Hereinafter, in case that at least one sub anode electrode is arbitrary referred to or two or more types of sub anode electrodes are comprehensively referred to among individual sub anode electrodes such as the (1-1)-th sub anode electrode SAE1-1, the (1-2)-th sub anode electrode SAE1-2, the (1-3)-th sub anode electrode SAE1-3, the (2-1)-th sub anode electrode SAE2-1, the (2-2)-th sub anode electrode SAE2-2, and the (2-3)-th sub anode electrode SAE2-3, the at least one sub anode electrode or the two or more types of sub anode electrodes is or are referred to as “anode electrode AE” or “anode electrodes AE”.

The (1-1)-th sub anode electrode SAE1-1, the (1-2)-th sub anode electrode SAE1-2, and the (1-3)-th sub anode electrode SAE1-3 may be disposed in the emission area EMA of the (1-1)-th sub-pixel SPXL1-1, the (1-2)-th sub-pixel SPXL1-2, and the (1-3)-th sub-pixel SPXL1-3, respectively, and may be spaced apart from each other.

The (2-1)-th sub anode electrode SAE2-1, the (2-2)-th sub anode electrode SAE2-2, and the (2-3)-th sub anode electrode SAE2-3 may be disposed in the emission area EMA of the (2-1)-th sub-pixel SPXL2-1, the (2-2)-th sub-pixel SPXL2-2, and the (2-3)-th sub-pixel SPXL2-3, respectively, and may be spaced apart from each other.

The (1-1)-th sub anode electrode SAE1-1, the (1-2)-th sub anode electrode SAE1-2, and the (1-3)-th sub anode electrode SAE1-3 may be electrically connected to the respectively first transistor electrode TE1 of the (1-1)-th sub-pixel SPXL1-1, (1-2)-th sub-pixel SPXL1-2, and (1-3)-th sub-pixel SPXL1-3, respectively, through a contact hole CH2 passing through the via layer VIA and the passivation layer PSV.

The pixel defining layer PDL may be disposed on the anode electrodes AE. The pixel defining layer PDL may define (or partition) the emission area EMA of each pixel PXL. The pixel defining layer PDL may include openings OP that partially expose the anode electrode AE of each pixel PXL. The openings OP of the pixel defining layer PDL may overlap the emission areas EMA of each pixel PXL.

The pixel defining layer PDL may be an organic insulating layer formed of an organic material. The organic material may include acryl resin, epoxy resin, phenolic resin, polyamide resin, polyimide resin, the like, or a combination thereof.

According to an embodiment, the pixel defining layer PDL may include a light absorbing material or may be coated with a light absorbing material to serve to absorb input light. For example, the pixel defining layer PDL may include a carbon-based black pigment. However, the disclosure is not necessarily limited thereto, and the pixel defining layer PDL may include an opaque metal material such as chromium (Cr), molybdenum (Mo), an alloy of molybdenum (Mo) and titanium (Ti) (MoTi), tungsten (W), vanadium (V), niobium (Nb), tantalum (Ta), manganese (Mn), cobalt (Co), nickel (Ni), or a combination thereof.

The light emitting element layers EML of each pixel PXL may be disposed on the respective anode electrodes AE exposed by the pixel defining layer PDL.

The light emitting element layers EML may include a first light emitting element layer EML1 corresponding to the first anode electrode AE1 and a second light emitting element layer corresponding to the second anode electrode AE2. As an example, the first light emitting element layer EML1 and the second light emitting element layer may be a front-surface emission organic light emitting element.

Specifically, the first light emitting element layer EML1 may include a (1-1)-th sub light emitting element layer SEML1-1 corresponding to the (1-1)-th sub anode electrode SAE1-1, a (1-2)-th sub light emitting element layer SEML1-2 corresponding to the (1-2)-th sub anode electrode SAE1-2, and a (1-3)-th sub light emitting element layer SEML1-3 corresponding to the (1-3)-th sub anode electrode SAE1-3.

Similarly, the second light emitting element layer may also include a (2-1)-th sub light emitting element layer corresponding to the (2-1)-th sub anode electrode, a (2-2)-th sub light emitting element layer corresponding to the (2-2)-th sub anode electrode, and a (2-3)-th sub light emitting element layer corresponding to (2-3)-th sub anode electrode.

The cathode electrode CE may be disposed on the light emitting element layer EML. The cathode electrode CE may be formed throughout the first pixel PXL1 or the second pixel PXL2. As an example, the cathode electrode CE may be provided as a common electrode to the (1-1)-th sub-pixel SPXL1-1, the (1-2)-th sub-pixel SPXL1-2, and the (1-3)-th sub-pixel SPXL1-3, but is not necessarily limited thereto.

The cathode electrode CE may be formed of a metal layer of silver (Ag), magnesium (Mg), aluminum (Al), platinum (Pt), palladium (Pd), gold (Au), nickel (Ni), neodymium (Nd), iridium (Ir), chromium (Cr), an alloy thereof, the like, or a combination thereof and/or a transparent conductive layer of indium tin oxide (ITO), indium zinc oxide (IZO), zinc oxide (ZnO), indium tin zinc oxide (ITZO), the like, or a combination thereof. According to an embodiment, the cathode electrode CE may be formed as multiple layers of two or more layers including a thin metal layer, for example, three layers of ITO/Ag/ITO.

Hereinafter, each anode electrode AE, and the light emitting element layer EML and cathode electrode CE corresponding to the corresponding anode electrode AE are collectively referred to as a light emitting element LD, the (1-1)-th to (1-3)-th sub light emitting elements SLD1-1, SLD1-2, and SLD1-3 corresponding to the first pixel PXL1 are referred to as a first light emitting element LD1, and (2-1)-th to (2-3)-th sub light emitting elements (not shown) corresponding to the second pixel PXL2 are referred to as a second light emitting element LD2.

In case that the light emitting element LD is a front-surface emission type, the anode electrode AE may be a reflective electrode, and the cathode electrode CE may be a transmissive electrode or a semi-transmissive electrode. In case that the light emitting element LD is a rear-surface emission type, the anode electrode AE may be a transmissive electrode or a semi-transmissive electrode, and the cathode electrode CE may be a reflective electrode. However, for convenience of description, the disclosure is described based on a case where the light emitting element LD is a front-surface emission type, and thus the anode electrode AE may be the reflective electrode and the cathode electrode CE may be the semi-transmissive electrode.

The thin film encapsulation layer TFE may be disposed on the display element layer DPL. The thin film encapsulation layer TFE may have a single layer structure or a multiple layer structure. The thin film encapsulation layer TFE may include multiple insulating layers covering the light emitting element LD. The thin film encapsulation layer TFE may include at least one inorganic layer and at least one organic layer. For example, the thin film encapsulation layer TFE may have a structure in which an inorganic layer and an organic layer may be alternately stacked on each other. According to an embodiment, the thin film encapsulation layer TFE may be an encapsulation substrate disposed on the light emitting element LD and bonded to the substrate SUB through a sealant. The thin film encapsulation layer TFE may cover the display element layer DPL and the pixel circuit layer PCL to protect the light emitting element LD from external moisture, heat, shock, and the like.

In order to improve encapsulation efficiency of the thin film encapsulation layer TFE, the thin film encapsulation layer TFE may further include a thin film including aluminum oxide (AlOₓ). The thin film including aluminum oxide may be positioned on an upper surface of the encapsulation layer TFE facing the window WD and/or on a lower surface of the thin film encapsulation layer TFE facing the display element layer DPL.

The thin film including aluminum oxide may be formed through atomic layer deposition (ALD), but is not necessarily limited thereto. According to embodiments, the thin film encapsulation layer TFE may further include a thin film formed of one of various materials suitable for improving encapsulation efficiency, and may be formed in a method suitable for a material of the thin film.

A light blocking layer LBP may be disposed on the thin film encapsulation layer TFE. The light blocking layer LBP may include an opening OP′ that may overlap the light emitting element LD. As an example, the light blocking layer LBP may be disposed to overlap the non-emission area NEMA around the emission area EMA.

The light blocking layer LBP may include a light blocking material to prevent light leakage and color mixing defects. As an example, the light blocking layer LBP may include a black matrix, but is not necessarily limited thereto. According to an embodiment, the light blocking layer LBP may include carbon black (CB) and/or titan black (TiBK).

The color filter layer CFL may be disposed on the light blocking layer LBP. The color filter layer CFL may include a first color filter layer CFL1 disposed on a first pixel PXL1 side and a second color filter layer (not shown) disposed on a second pixel PXL2 side.

Specifically, the first color filter layer CFL1 may include sub color filters SCF1-1, SCF1-2, and SCF1-3 matching a color of each pixel PXL. As (1-1)-th to (1-3)-th sub color filters SCF1-1, SCF1-2, and SCF1-3 matching a color of the respective (1-1)-th to (1-3)-th sub-pixels PXL1-1, PXL1-2, and PXL1-3 may be disposed, a full color image may be displayed.

For example, the first color filter layer CFL1 may include the (1-1)-th sub color filter SCF1-1 disposed in the (1-1)-th sub-pixel SPXL1-1 and selectively transmitting light emitted from the (1-1)-th sub-pixel SPXL1-1, the (1-2)-th sub color filter SCF1-2 disposed in the (1-2)-th sub-pixel SPXL1-2 and selectively transmitting light emitted from the (1-2)-th sub-pixel SPXL1-2, and the (1-3)-th sub color filter SCF1-3 disposed in the (1-3)-th sub-pixel SPXL1-3 and selectively transmitting light emitted from the (1-3)-th sub-pixel SPXL1-3.

In an embodiment, the (1-1)-th to (1-3)-th sub color filters SCF1-1, SCF1-2, and SCF1-3 may be a red color filter, a green color filter, and a blue color filter, respectively, but are not necessarily limited thereto. Hereinafter, in case that an arbitrary sub color filter may be referred to or two or more types of sub color filters are comprehensively referred to among the (1-1)-th sub color filter SCF1-1, the (1-2)-th sub color filter SCF1-2, and the (1-3)-th sub color filter SCF1-3, the arbitrary sub color filter or the two or more types of sub color filters is or are referred to as “color filter CFL1” or “color filters CFL1”.

The (1-1)-th sub color filter SCF1-1 may include a color filter material that selectively transmits light of a first color (or red). For example, in case that the (1-1)-th sub-pixel SPXL1-1 is a red pixel, the (1-1)-th sub color filter SCF1-1 may include a red color filter material.

The (1-2)-th sub color filter SCF1-2 may include a color filter material that selectively transmits light of a second color (or green). For example, in case that the (1-2)-th sub-pixel SPXL1-2 is a green pixel, the (1-2)-th sub color filter SCF1-2 may include a green color filter material.

The (1-3)-th sub color filter SCF1-3 may include a color filter material that selectively transmits light of a third color (or blue). For example, in case that the (1-3)-th sub-pixel SPXL1-3 is a blue pixel, the (1-3)-th sub color filter SCF1-3 may include a blue color filter material.

The window WD may be provided on the color filter layer CFL. The window WD may protect a lower member from external shock and provide an input surface and/or a display surface to the user.

Hereinafter, the via layer VIA is described in more detail.

Referring to FIGS. 4, 5A, and 5B together, the via layer VIA may be interposed between the pixel circuit layer PCL and the display element layer DPL. Multiple slit patterns SLP that overlap each of the anode electrodes AE provided in the light emitting element LD may be formed on an upper surface of the via layer VIA facing the display element layer DPL.

The slit pattern SLP may include a first slit pattern SLP1 formed on the upper surface of the via layer VIA overlapping the first anode electrode AE1, and a second slit pattern SLP2 formed on the upper surface of the via layer VIA overlapping the second anode electrode AE2.

The first slit pattern SLP1 and the second slit pattern SLP2 may be formed to be different from each other in at least one of a shape, a size, and a position.

Specifically, hereinafter, “shape” may refer to the overall shape of a specific component it refers to, and when comparing a specific component with another component, even though sizes or positions may be different from each other, in case that the overall shape of each compared component is substantially the same, it is expressed as “shape is the same”.

Here, “substantially the same” may include not only being completely the same, but may also comprehensively mean being similar or close in a range that allows for a certain degree of error due to a process condition, a material property, or the like.

The word “size” may refer to the overall area occupied by a specific component it refers to, and when comparing a specific component with another component, even though shapes or positions may be different from each other, in case that the overall area of each compared component is substantially the same, it is expressed as “size is the same.”

The word “position” may refer to considering both of a center of a specific component it may refer to and a degree of rotation based on the center, and when comparing a specific component with another component, even though shapes or sizes may be different from each other, in case that the center of each compared component and the degree of rotation relative to the center are substantially the same, it is expressed as “position is the same”. In case that centers of the compared components are substantially the same, but the degree of rotation relative to the centers is different, the corresponding components are expressed as “having different positions”.

As an example, FIG. 4 illustrates a case where shapes of the first slit pattern SLP1 and the second slit pattern SLP2 may be different from each other. For example, the first slit pattern SLP1 may have a rectangular shape with a rounded corner, and the second slit pattern SLP2 may have an elliptical shape, but are not necessarily limited thereto. According to an embodiment, the first slit pattern SLP1 and the second slit pattern SLP2 may have various shapes such as a circular shape, a square shape, a polygonal shape, and an elliptical shape.

The slit pattern SLP may have a concave schematic cross-section as a shape recessed at a depth (e.g., predetermined or selectable depth) in a direction from the upper surface of the via layer VIA to the substrate SUB. Accordingly, a lower surface of the anode electrode AE that may be in contact with the slit pattern SLP may have a shape complementary to the slit pattern SLP. For example, a portion of the anode electrode AE formed on the via layer VIA, which may be in contact with the slit pattern SLP, may also have a concave schematic cross-section identically to the slit pattern SLP.

The portion where the anode electrode AE and the slit pattern SLP overlap each other may be preferably positioned in the emission area EMA defined in each pixel PXL, but is not necessarily limited thereto. According to an embodiment, the portion where the anode electrode AE and the slit pattern SLP overlap each other may extend to the non-emission area NEMA.

The anode electrode AE may reflect light emitted from the light emitting element layer EML, and a portion which may not be emitted to an outside through the cathode electrode CE among the light reflected from the anode electrode AE may be reflected from the cathode electrode CE again and may be directed toward the anode electrode AE.

As described above, the light emitted from the light emitting layer EML may be continuously reflected between the anode electrode AE and the cathode electrode CE, and thus a resonance phenomenon of light may occur. At this time, due to the concave schematic cross-sectional shape of the anode electrode AE, light resonating between the anode electrode AE and the cathode electrode CE may have the same or similar wavelength, but the light may be emitted to the outside in different directions.

For example, as a wavelength of light emitted from the light emitting element LD in a Z direction (for example, a front surface of the display panel from a user's perspective) and a wavelength of light emitted in a direction intersecting the Z direction (for example, a side surface from the user's perspective) have the same wavelength, since the user who sees the light emitted from the light emitting element LD from the outside may see the same light from the front surface and the side surface of the display panel PNL, an effect of improving visibility may be expected.

Since the first pixel PXL1 and the second pixel PXL2 may be disposed adjacent to each other, in case that light of the same wavelength is emitted from the first pixel PXL1 and the second pixel PXL2 in the same direction in an overlapping manner, the user may see a diffraction pattern.

In case that all of the shape, the size, and the position of the first slit pattern SLP1 and the second slit pattern SLP2 are the same, light of the same wavelength reflected from the first anode electrode AE1 and the second anode electrode AE2 may be radiated in the same direction, and thus the user may see a diffraction pattern.

According to an embodiment, since the first slit pattern SLP1 and the second slit pattern SLP2 have different shapes, the light of the same wavelength reflected from the first anode electrode AE1 and the second anode electrode AE2 may be radiated in different directions. From the user's perspective, the wavelength of the light seen from the first pixel PXL1 and the wavelength of the light seen from the second pixel PXL2 may be different from each other at a specific position, and thus less diffraction patterns may be seen, thereby improving visibility of the user looking at the display panel PNL.

The first slit pattern SLP1 may include a (1-1)-th sub slit pattern SSLP1-1 formed on the upper surface of the via layer VIA overlapping the (1-1)-th sub anode electrode SAE1-1, a (1-2)-th sub slit pattern SSLP1-2 formed on the upper surface of the via layer VIA overlapping the (1-2)-th sub anode electrode SAE1-2, and a (1-3)-th sub slit pattern SSLP1-3 formed on the upper surface of the layer VIA overlapping the (1-3)-th sub anode electrode SAE1-3.

Similarly, the second slit pattern SLP2 may include a (2-1)-th sub slit pattern SSLP2-1 formed on the upper surface of the via layer VIA overlapping the (2-1)-th sub anode electrode SAE2-1, a (2-2)-th sub slit pattern SSLP2-2 formed on the upper surface of the via layer VIA overlapping the (2-2)-th sub anode electrode SAE2-2, and a (2-3)-th sub slit pattern SSLP2-3 formed on the upper surface of the layer VIA overlapping the (2-3)-th sub anode electrode SAE2-3.

Hereinafter, in case that at least one sub slit pattern is arbitrary referred to or two or more types of sub slit patterns are comprehensively referred to among individual sub slit patterns among the (1-1)-th sub slit pattern SSLP1-1, the (1-2)-th sub slit pattern SSLP1-2, the (1-3)-th sub slit pattern SSLP1-3, the (2-1)-th sub slit pattern SSLP2-1, the (2-2)-th sub slit pattern SSLP2-2, and the (2-3)-th sub slit pattern SSLP2-3, the at least one sub slit pattern or the two or more types of sub slit patterns is or are referred to as “slit pattern SLP” or “slit patterns SLP”.

Referring to FIG. 4 again, the (1-1)-th to (1-3)-th sub slit patterns SSLP1-1, SSLP1-2, and SSLP1-3 may have substantially the same shape and size and may be formed at the same position. Similarly, the (2-1)-th to (2-3)-th sub slit patterns SSLP2-1, SSLP2-2, and SSLP2-3 may also have substantially the same shape and size and may have the same position.

As described above, the slit pattern SLP may have the same shape, size, and position in one and the same pixel PXL, for example, the first pixel PXL1 or the second pixel PXL2, and this may be for setting a light characteristic implemented through a pixel PXL as consistently as possible.

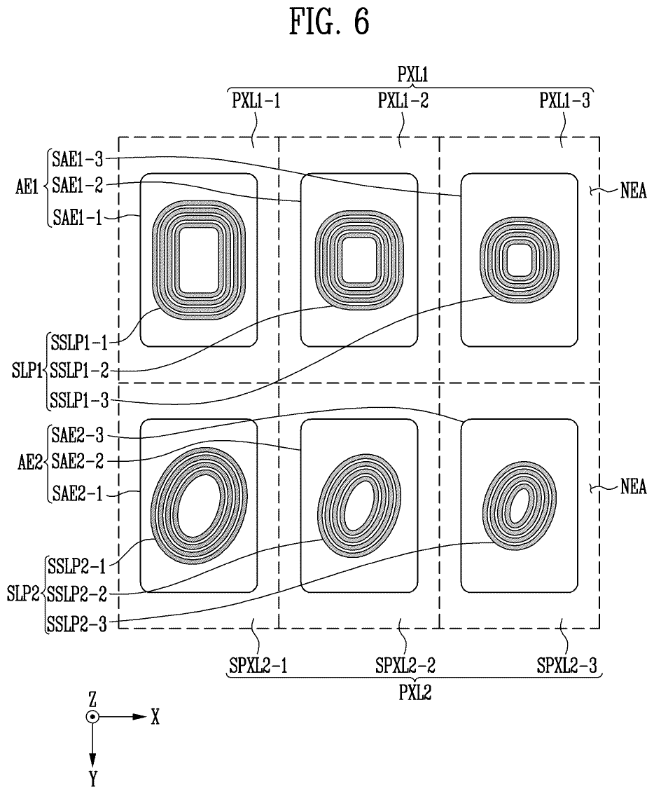

FIG. 6 is a plan view illustrating an embodiment of the first slit pattern and the second slit pattern shown in FIG. 4.

Referring to FIG. 6, the shapes of the first slit pattern SLP1 and the second slit pattern SLP2 may be different from each other in that the shapes may be a circular shape and a quadrangular shape with a rounded corner, respectively. The (1-1)-th to (1-3)-th sub slit patterns SSLP1-1, SSLP1-2, and SSLP1-3 may have different sizes, and the (2-1)-th to (2-3)-th sub slit patterns SSLP2-1, SSLP2-2, and SSLP2-3 may also have different sizes.

However, here, the (1-1)-th to (1-3)-th sub slit patterns SSLP1-1, SSLP1-2, and SSLP1-3 may have the same position, and the (2-1)-th to (2-3)-th sub slit patterns SSLP2-1, SSLP2-2, and SSLP2-3 may also have the same position.

Although the sizes of the (1-1)-th sub slit pattern SSLP1-1 and the (1-2)-th sub slit pattern SSLP1-2, and the (2-1)-th sub slit pattern SSLP2-1 and the (2-2)-th sub slit pattern SSLP2-2 may be different, the shapes of the (1-1)-th sub slit pattern SSLP1-1 and the (2-1)-th sub slit pattern SSLP2-1, the (1-2)-th sub slit pattern SSLP1-2 and the (2-2)-th sub slit pattern SSLP2-2, and the (1-3)-th sub slit pattern SSLP1-3 and the (2-3)-th sub slit pattern SSLP2-3 may be different, even though light of the same wavelength may be emitted from adjacent pixels, such as the first pixel PXL1 and the second pixel PXL2, the light may be radiated in different directions.

Therefore, even with the above structure, from the user's perspective, since the wavelength of light seen from the display panel PNL at a specific position may be different, a less diffraction pattern may be seen, and furthermore, visibility of the user looking at the display panel PNL may be improved.

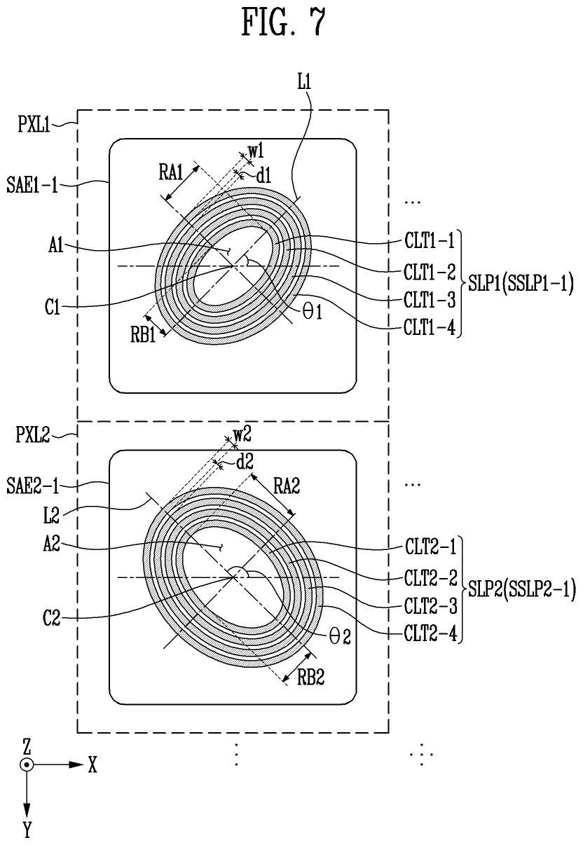

Hereinafter, a case where both of the first slit pattern SLP1 and the second slit pattern SLP2 have an elliptical shape is described in more detail with reference to FIG. 7.

FIG. 7 is a plan view illustrating an embodiment of the (1-1)-th sub slit pattern and the (2-1)-th sub slit pattern.

Referring to FIG. 7, both of the (1-1)-th sub slit pattern SSLP1-1 and the (2-1)-th sub slit pattern SSLP2-1 may have an elliptical shape. Here, the (1-1)-th sub slit pattern SSLP1-1 may represent the first slit pattern SLP1, and the (2-1)-th sub slit pattern SSLP2-1 may represent the second slit pattern SLP2. Although not shown, the (1-2)-th sub slit pattern SSLP1-2, the (1-3)-th sub slit pattern SSLP1-3, the (2-2)-th sub slit pattern SSLP2-2, and the (2-3)-th sub slit pattern SSLP2-3 may also have an elliptical shape similar to the (1-1)-th sub slit pattern SSLP1-1 and the (2-1)-th sub slit pattern SSLP2-1.

Therefore, hereinafter, for convenience of description, the (1-1)-th sub slit pattern SSLP1-1 is referred to as the first slit pattern SLP1, and the (2-1)-th sub slit pattern SSLP2-1 is referred to as the second slit pattern SLP2.

The first slit pattern SLP1 may have a first center C1 at a viewpoint looking at the first pixel PXL1 in a direction in which a Z-axis extends, and the second slit pattern SLP2 may have a second center C2 at a view point looking at the second pixel PXL2 in the direction in which the Z-axis extends. At this time, the first center C1 and the second center C2 may be formed at substantially the same position, respectively, in an area occupied by the (1-1)-th sub anode electrode SAE1-1 and the (2-1)-th sub anode electrode SAE2-1 in the first pixel PXL1 and the second pixel PXL2, respectively.

The first slit pattern SLP1 may include a (1-1)-th trench CLT1-1, a (1-2)-th trench CLT1-2, a (1-3)-th trench CLT1-3, and (1-4)-th trench CLT1-4 of a closed-loop shape formed sequentially and spaced apart from each other in a radial direction with respect to the first center C1. The second slit pattern SLP2 also may include a (2-1)-th trench CLT2-1, a (2-2)-th trench CLT2-2, a (2-3)-th trench CLT2-3, and (2-4)-th trench CLT2-4 of a closed-loop shape formed sequentially and spaced apart from each other in a radial direction with respect to the second center C2.

As described above, each of the first slit pattern SLP1 and the second slit pattern SLP2 may have four trenches, but the number thereof is not necessarily limited thereto. According to an embodiment, each of the first slit pattern SLP1 and the second slit pattern SLP2 may have multiple trenches.

More specifically, a first area A1 of the first slit pattern SLP1 surrounded by the (1-1)-th trench CLT1-1 and a second area A2 of the second slit pattern SLP2 surrounded by the (2-1)-th trench CLT2-1 may have different areas.

Each of the (1-1)-th to (1-4)-th trenches CLT1-1, CLT1-2, CLT1-3, and CLT1-4 may have a width w1 of about 1.5 μm or less in the radial direction with respect to the first center C1. Each of the (2-1)-th to (2-4)-th trenches CLT2-1, CLT2-2, CLT2-3, and CLT2-4 may have a width w2 of about 1.5 μm or less in the radial direction with respect to the second center C2.

The respective trenches, for example, the (1-1)-th trench CLT1-1 and the (1-2)-th trench CLT1-2, the (1-2)-th trench CLT1-2 and the (1-3)-th trench CLT1-3, or the (1-3)-th trench CLT1-3 and the (1-4)-th trench CLT1-4 may be spaced apart from each other by a distance d1 of about 1.5 μm or less in the radial direction with respect to the first center C1.

The (2-1)-th trench CLT2-1 and the (2-2)-th trench CLT2-2, the (2-2)-th trench CLT2-2 and the (2-3)-th trench CLT2-3, or the (2-3)-th trench CLT2-3 and the (2-4)-th trench CLT2-4 may also be spaced apart from each other by a distance d2 of about 1.5 μm or less in the radial direction with respect to the second center C2.

In case that a distance farthest from the (1-1)-th trench CLT1-1 based on the first center C1 is defined as a first major radius RA1 and a distance farthest from the (2-1)-th trench CLT2-1 based on the second center C2 is defined as a second major radius RA2, a virtual line L1 extending in the first major radius RA1 and a virtual line L2 extending in the second major radius RA2 may intersect each other.

Here, the meaning of the statement “the virtual line L1 extending in the first major radius RA1 and the virtual line L2 extending in the second major radius RA2 intersect each other” means that an angle θ1 formed by the first major radius RA1 with an X-axis and an angle θ2 formed by the second major radius RA2 with the X-axis may be different from each other, and means that degrees at which the first slit pattern SLP1 and the second slit pattern SLP2 rotate about the first center C1 and the second center C2, respectively, may be different from each other.

Furthermore, although the first center C1 and the second center C2 may be formed at substantially the same position in the (1-1)-th sub anode electrode SAE1-1 and the (2-1)-th sub anode electrode SAE2-1, respectively, since the degrees at which the first slit pattern SLP1 and the second slit pattern SLP2 rotate about the first center C1 and the second center C2, respectively, may be different from each other, the positions of the first slit pattern SLP1 and the second slit pattern SLP2 may not be the same.

Therefore, even with this structure, even though light of the same wavelength may be radiated from each of the first pixel PXL1 and the second pixel PXL2, since the light may be radiated in different directions, from the user's perspective, the wavelengths of light seen from the display panel PNL may be different from each other, and thus a less diffraction pattern may be seen, thereby improving visibility of the user looking at the display panel PNL.

In case that the first slit pattern SLP1 and/or the second slit pattern SLP2 are formed in an elliptical shape, it may be desirable that an eccentricity of the corresponding ellipse may be about 0.7 or less. More specifically, in case that a separation distance closest to the (1-1)-th trench CLT1-1 based on the first center C1 is defined as a first minor radius RB1 and a separation distance closest to the (2-1)-th trench CLT2-1 is defined as a second minor radius RB2, the following formulas may be satisfied.

$${( 1 - {( RB 1 )}^{2} / {( RA 1 )}^{2} )}^{1 / 2} \leq 0.7 \qquad [ Formula 1 ]$$

$${( 1 - {( RB 2 )}^{2} / {( RA 2 )}^{2} )}^{1 / 2} \leq 0.7 \qquad [ Formula 2 ]$$

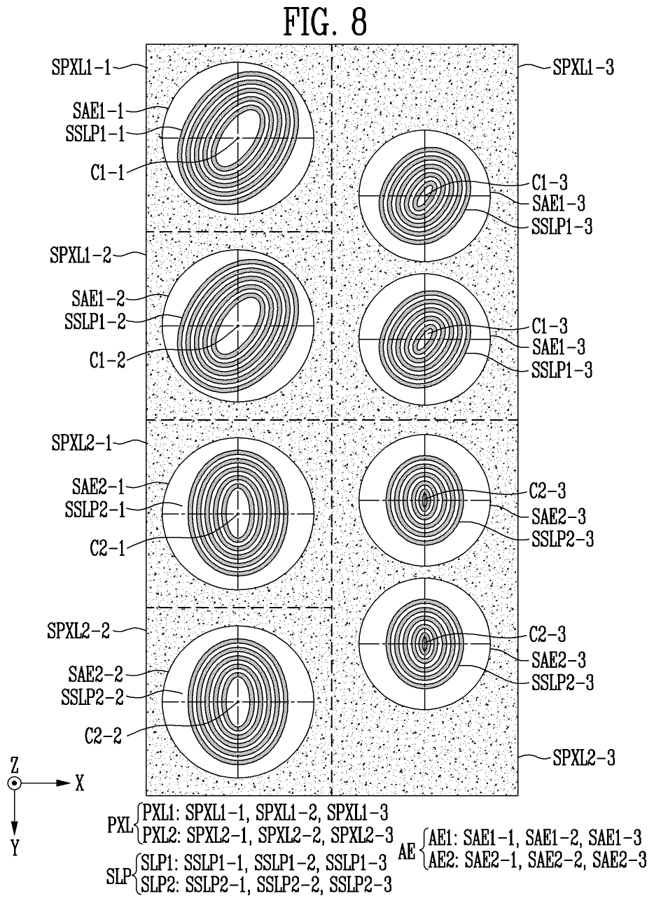

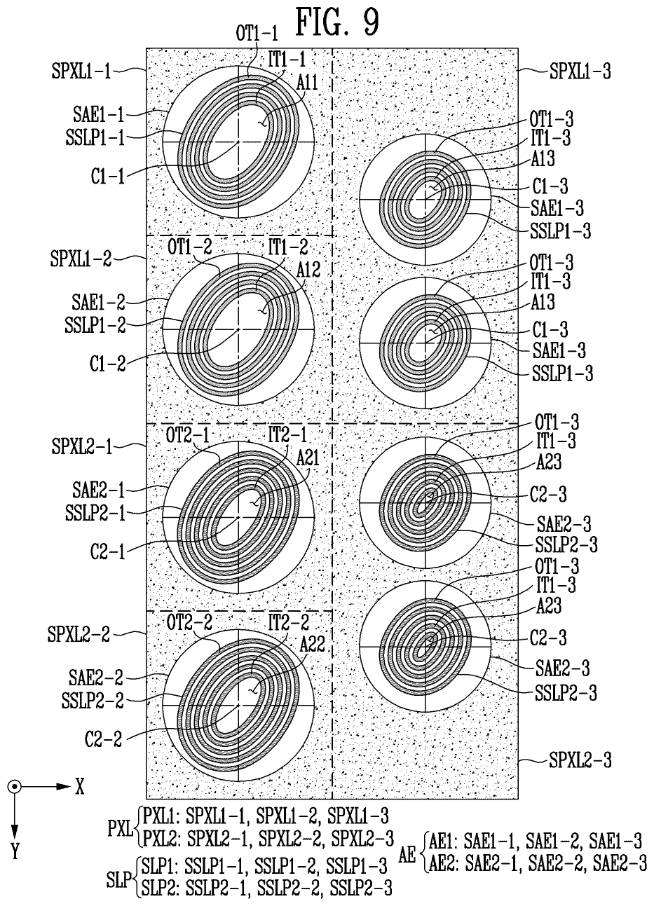

Hereinafter, with reference to FIGS. 8 and 9, an embodiment in which an arrangement and a structure of the sub-pixels in the first pixel PXL1 and the second pixel PXL2 may be different from those described above is described.

FIG. 8 is a plan view illustrating an embodiment of two pixels adjacent to each other among the pixels of FIG. 3, and FIG. 9 is a plan view illustrating an embodiment of the first slit pattern and the second slit pattern shown in FIG. 8.

Referring to FIGS. 8 and 9, the first pixel PXL1 may include a (1-1)-th sub-pixel SPXL1-1, a (1-2)-th sub-pixel SPXL1-2, and a (1-3)-th sub-pixel SPXL1-3. The second pixel PXL2 may include a (2-1)-th sub-pixel SPXL2-1, a (2-2)-th sub-pixel SPXL2-2, and a (2-3)-th sub-pixel SPXL2-3.

The (1-1)-th sub-pixel SPXL1-1 and the (1-2)-th sub-pixel SPXL1-2 may be sequentially arranged in a Y-axis direction, and the (1-3)-th sub-pixel SPXL1-3 may be sequentially arranged in an X-axis direction so as to be adjacent to both of the (1-1)-th sub-pixel SPXL1-1 and the (1-2)-th sub-pixel SPXL1-2.

The (2-1)-th sub-pixel SPXL2-1 and the (2-2)-th sub-pixel SPXL2-2 may also be sequentially arranged in the Y-axis direction, and the (2-3)-th sub-pixel SPXL2-3 may be sequentially arranged in the Y-axis direction so as to be adjacent to both of the (2-1)-th sub-pixel SPXL2-1 and the (2-2)-th sub-pixel SPXL2-2.

The first anode electrode AE1 may include a (1-1)-th sub anode electrode SAE1-1 corresponding to the (1-1)-th sub-pixel SPXL1-1, a (1-2)-th sub anode electrode SAE1-2 corresponding to the (1-2)-th sub-pixel SPXL1-2, and a (1-3)-th sub anode electrode SAE1-3 corresponding to the (1-3)-th sub-pixel SPXL1-3.

The (1-1)-th to (1-3)-th sub anode electrodes SAE1-1, SAE1-2, and SAE1-3 may be arranged on a plane formed by an X-axis and a Y-axis identically to a structure in which each of the (1-1)-th to (1-3)-th sub-pixels SPXL1-1, SPXL1-2, and SPXL1-3 may be arranged in the X-axis and Y-axis directions.

The (1-1)-th sub anode electrode SAE1-1 and the (1-2)-th sub anode electrode SAE1-2 may be formed one by one in the (1-1)-th sub-pixel SPXL1-1 and the (1-2)-th sub-pixel SPXL1-2, respectively. In a case of the (1-3)-th sub anode electrode SAE1-3, two may be formed in the (1-3)-th sub-pixel SPXL1-3 and arranged sequentially in the Y-axis direction, but the disclosure is not necessarily limited thereto. According to an embodiment, at least one (1-1)-th sub anode electrode SAE1-1, at least one (1-2)-th sub anode electrode SAE1-2, and at least one (1-3)-th sub anode electrode SAE1-3 may be formed in the (1-1)-th to (1-3)-th sub-pixels SPXL1-1, SPXL1-2, and SPXL1-3, respectively.

The second anode electrode AE2 also may include a (2-1)-th sub anode electrode SAE2-1 corresponding to the (2-1)-th sub-pixel SPXL2-1, a (2-2)-th sub anode electrode SAE2-2 corresponding to the (2-2)-th sub-pixel SPXL2-2, and a (2-3)-th sub anode electrode SAE2-3 corresponding to the (2-3)-th sub-pixel SPXL2-3.

The (2-1)-th to (2-3)-th sub anode electrodes SAE2-1, SAE2-2, and SAE2-3 may be arranged on the plane formed by the X-axis and the Y-axis identically to a structure in which each of the (2-1)-th to (2-3)-th sub-pixels SPXL2-1, SPXL2-2, and SPXL2-3 may be arranged in the X-axis and Y-axis directions.

The (2-1)-th sub anode electrode SAE2-1 and the (2-2)-th sub anode electrode SAE2-2 may be formed one by one in the (2-1)-th sub-pixel SPXL2-1 and the (2-2)-th sub-pixel SPXL2-2, respectively. In a case of the (2-3)-th sub anode electrode SAE2-3, two may be formed in the (2-3)-th sub-pixel SPXL2-3 and arranged sequentially in the Y-axis direction, but the disclosure is not necessarily limited thereto. According to an embodiment, at least one (2-1)-th sub anode electrode SAE2-1, at least one (2-2)-th sub anode electrode SAE2-2, and at least one (2-3)-th sub anode electrode SAE2-3 may be formed in the (2-1)-th to (2-3)-th sub-pixels SPXL2-1, SPXL2-2, and SPXL2-3, respectively.

The first slit pattern SLP1 may include a (1-1)-th sub slit pattern SSLP1-1 corresponding to the (1-1)-th sub anode electrode SAE1-1, a (1-2)-th sub slit pattern SSLP1-2 corresponding to the (1-2)-th sub anode electrode SAE1-2, and a (1-3)-th sub slit pattern SSLP1-3 corresponding to the (1-3)-th sub anode electrode SAE1-3.

The (1-1)-th to (1-3)-th sub slit patterns SSLP1-1, SSLP1-2, and SSLP1-3 may be arranged on a plane formed by the X-axis and the Y-axis identically to a structure in which each of the (1-1)-th to (1-3)-th sub anode electrodes SAE1-1, SAE1-2, and SAE1-3 may be arranged in the X-axis and Y-axis directions.

The (1-1)-th sub slit pattern SSLP1-1 and the (1-2)-th sub slit pattern SSLP1-2 may have a one-to-one correspondence with the (1-1)-th sub anode electrode SAE1-1 and the (1-2)-th sub anode electrode SAE1-2 in the (1-1)-th sub pixel SPXL1-1 and the (1-2)-th subpixel SPXL1-2, respectively. In a case of the (1-3)-th sub slit pattern SSLP1-3, a total of two may be formed in the (1-3)-th sub pixel PXL1-3 and may have a one-to-one correspondence with the (1-3)-th sub anode electrodes SAE1-3 arranged sequentially in the Y-axis direction, but the disclosure is not necessarily limited thereto. According to an embodiment, at least one (1-1)-th sub slit pattern SSLP1-1, at least one (1-2)-th sub slit pattern SSLP1-2, and at least one (1-3)-th sub slit pattern SSLP1-3 may be formed in the (1-1)-th to (1-3)-th sub anode electrodes SAE1-1, SAE1-2, and SAE1-3, respectively.

The second slit pattern SLP2 may include a (2-1)-th sub slit pattern SSLP2-1 corresponding to the (2-1)-th sub anode electrode SAE2-1, a (2-2)-th sub slit pattern SSLP2-2 corresponding to the (2-2)-th sub anode electrode SAE2-2, and a (2-3)-th sub slit pattern SSLP2-3 corresponding to the (2-3)-th sub anode electrode SAE2-3.

The (2-1)-th to (2-3)-th sub slit patterns SSLP2-1, SSLP2-2, and SSLP2-3 may be arranged on a plane formed by the X-axis and the Y-axis identically to a structure in which each of the (2-1)-th to (2-3)-th sub anode electrodes SAE2-1, SAE2-2, and SAE2-3 may be arranged in the X-axis and Y-axis directions.

The (2-1)-th sub slit pattern SSLP2-1 and the (2-2)-th sub slit pattern SSLP2-2 may be formed one by one in the (2-1)-th sub anode electrode SAE2-1 and the (2-2)-th sub anode electrode SAE2-2, respectively. In a case of the (2-3)-th sub slit pattern SSLP2-3, a total of two may be formed one by one in the (2-3)-th sub anode electrode SAE2-3 and arranged sequentially in the Y-axis direction, but the disclosure is not necessarily limited thereto. According to an embodiment, at least one (2-1)-th sub slit pattern SSLP2-1, at least one (2-2)-th sub slit pattern SSLP2-2, and at least one (2-3)-th sub slit pattern SSLP2-3 may be formed in the (2-1)-th to (2-3)-th sub anode electrodes SAE2-1, SAE2-2, and SAE2-3, respectively.

In particular, FIGS. 8 and 9 illustrate a case where all of the (1-1)-th to (1-3)-th sub slit patterns SSLP1-1, SSLP1-2, and SSLP1-3 and the (2-1)-th to (2-3)-th sub slit patterns SSLP2-1, SSLP2-2, and SSLP2-3 have an elliptical shape. Hereinafter, variations of the slit patterns SLP shown in FIGS. 8 and 9 are compared and described.

Specifically, FIG. 8 illustrates a case where positions of the respective sub slit patterns SSLP formed in the sub-pixels SPXL of the same position in each of the first pixel PXL1 and the second pixel PXL2 adjacent to each other may be different from each other. FIG. 9 illustrates a case where sizes of the respective sub slit pattern formed in the sub-pixels of the same position in each of the first pixel PXL1 and the second pixel PXL2 adjacent to each other may be different from each other.

First, referring to FIG. 8, the (1-1)-th to (1-3)-th sub slit patterns SSLP1-1, SSLP1-2, and SSLP1-3 may have the same elliptical shape as described above, and may have substantially the same center C1-1, C1-2, and C1-3 in the (1-1)-th to (1-3)-th sub anode electrodes SAE1-1, SAE1-2, and SAE1-3 where the respective (1-1)-th to (1-3)-th sub slit patterns SSLP1-1, SSLP1-2, and SSLP1-3 may be positioned.

The (1-1)-th sub slit pattern SSLP1-1 and the (1-2)-th sub slit pattern SSLP1-2 may have substantially the same size, and the (1-3)-th sub slit pattern SSLP1-3 may have a size different from that of the (1-1)-th sub slit pattern SSLP1-1 and the (1-2)-th sub slit pattern SSLP1-2, but this is an example and is not necessarily limited thereto. According to an embodiment, the (1-3)-th sub slit pattern SSLP1-3 may have substantially the same size as the (1-1)-th sub slit pattern SSLP1-1 and the (1-2)-th sub slit pattern SSLP1-2.

All degrees at which the (1-1)-th to (1-3)-th sub slit patterns SSLP1-1, SSLP1-2, and SSLP1-3 rotate about the respective centers C1-1, C1-2, and C1-3 may be substantially the same. For example, since the respective centers C1-1, C1-2, and C1-3 and the degrees at which the (1-1)-th to (1-3)-th sub slit patterns SSLP1-1, SSLP1-2, and SSLP1-3 rotate about the respective centers C1-1, C1-2, and C1-3 may be substantially the same, the (1-1)-th to (1-3)-th sub slit patterns SSLP1-1, SSLP1-2, and SSLP1-3 may have substantially the same position.

Therefore, summarizing that described above, all of the (1-1)-th to (1-3)-th sub slit patterns SSLP1-1, SSLP1-2, and SSLP1-3 shown in FIG. 8 may be the first slit patterns SLP1 formed in the same pixel, for example, the first pixel PXL1, and may have substantially the same shape and position. Although the size of the (1-3)-th sub slit pattern SSLP1-3 may be different from the size of the (1-1)-th sub slit pattern SSLP1-1 and the (1-2)-th sub slit pattern SSLP1-2, but this is only an example and may have substantially the same size.

Similarly, all of the (2-1)-th to (2-3)-th sub slit patterns SSLP2-1, SSLP2-2, and SSLP2-3 may also have the same elliptical shape as described above, and may have substantially the same center C2-1, C2-2, and C2-3 in the (2-1)-th to (2-3)-th sub anode electrodes SAE2-1, SAE2-2, and SAE2-3 where the respective (2-1)-th to (2-3)-th sub slit patterns SSLP2-1, SSLP2-2, and SSLP2-3 may be positioned.

The (2-1)-th sub slit pattern SSLP2-1 and the (2-2)-th sub slit pattern SSLP2-2 may have substantially the same size, and the (2-3)-th sub slit pattern SSLP2-3 may have a size different from that of the (2-1)-th sub slit pattern SSLP2-1 and the (2-2)-th sub slit pattern SSLP2-2, but this is an example and is not necessarily limited thereto. According to an embodiment, the (2-3)-th sub slit pattern SSLP2-3 may have substantially the same size as the (2-1)-th sub slit pattern SSLP2-1 and the (2-2)-th sub slit pattern SSLP2-2.

All degrees at which the (2-1)-th to (2-3)-th sub slit patterns SSLP2-1, SSLP2-2, and SSLP2-3 rotate about the respective centers C2-1, C2-2, and C2-3 may be substantially the same. For example, since the respective centers C2-1, C2-2, and C2-3 and the degrees at which the (2-1)-th to (2-3)-th sub slit patterns SSLP2-1, SSLP2-2, and SSLP2-3 rotate about the respective centers C2-1, C2-2, and C2-3 may be substantially the same, the (2-1)-th to (2-3)-th sub slit patterns SSLP2-1, SSLP2-2, and SSLP2-3 may have substantially the same position as described above.

Therefore, summarizing that described above, all of the (2-1)-th to (2-3)-th sub slit patterns SSLP2-1, SSLP2-2, and SSLP2-3 may be the second slit patterns SLP2 formed in the same pixel, for example, the second pixel PXL2, and may have substantially the same shape and position. Although the size of the (2-3)-th sub slit pattern SSLP2-3 may be different from the size of the (2-1)-th sub slit pattern SSLP2-1 and the (2-2)-th sub slit pattern SSLP2-2, this is only an example and may have substantially the same size.

As described above, the slit pattern SLP may have the same shape, size, and position in a same pixel PXL, and this is for setting the light characteristic implemented through a pixel PXL as consistently as possible.

The sub slit patterns formed in the sub-pixels of the same position in each of the first pixel PXL1 and the second pixel PXL2 adjacent to each other may have substantially the same shape and size, but positions thereof may be different from each other.

Specifically, comparing the (1-1)-th sub slit pattern SSLP1-1 and the (2-1)-th sub slit pattern SSLP2-1 formed in the (1-1)-th sub-pixel SPXL1-1 and the (2-1)-th sub-pixel SPXL2-1 positioned at an upper left of the first pixel PXL1 and the second pixel PXL2, respectively, both of the (1-1)-th sub slit pattern SSLP1-1 and the (2-1)-th sub slit pattern SSLP2-1 may have substantially the same elliptical shape, and may have substantially the same size and substantially the same center C1-1 and C2-1 in the (1-1)-th sub anode electrode SAE1-1 and the (2-1)-th sub anode electrode SAE2-1, respectively.

However, the degrees at which the (1-1)-th sub slit pattern SSLP1-1 and the (2-1)-th sub slit pattern SSLP2-1 rotate about the respective centers C1-1 and C2-1 may be different. For example, as described above, the (1-1)-th sub slit pattern SSLP1-1 and the (2-1)-th sub slit pattern SSLP2-2 may have different positions.

Comparing the (1-2)-th sub slit pattern SSLP1-2 and the (2-2)-th sub slit pattern SSLP2-2 formed in the (1-2)-th sub-pixel SPXL1-2 and the (2-2)-th sub-pixel SPXL2-2 positioned at an lower left of the first pixel PXL1 and the second pixel PXL2, respectively, both of the (1-2)-th sub slit pattern SSLP1-2 and the (2-2)-th sub slit pattern SSLP2-2 may have substantially the same elliptical shape, and may have substantially the same size and substantially the same center C1-2 and C2-2 in the (1-2)-th sub anode electrode SAE1-2 and the (2-2)-th sub anode electrode SAE2-2, respectively.

However, the degrees at which the (1-2)-th sub slit pattern SSLP1-2 and the (2-2)-th sub slit pattern SSLP2-2 rotate about the respective centers C1-2 and C2-2 may be different. For example, as described above, the (1-2)-th sub slit pattern SSLP1-2 and the (2-2)-th sub slit pattern SSLP2-2 may also have different positions.

Comparing the (1-3)-th sub slit pattern SSLP1-3 and the (2-3)-th sub slit pattern SSLP2-3 formed in the (1-3)-th sub-pixel SPXL1-3 and the (2-3)-th sub-pixel SPXL2-3 positioned at a right of the first pixel PXL1 and the second pixel PXL2, respectively, both of the (1-3)-th sub slit pattern SSLP1-3 and the (2-3)-th sub slit pattern SSLP2-3 may have substantially the same elliptical shape, and may have substantially the same size in the (1-3)-th sub anode electrode SAE1-3 and the (2-3)-th sub anode electrode SAE2-3, respectively.

However, centers of the (1-3)-th sub slit patterns SSLP1-3 and the (2-3)-th sub slit patterns SSLP2-3 in the (1-3)-th sub anode electrodes SAE1-3 and the (2-3)-th sub anode electrodes SAE2-3 may be different from each other, respectively. Degrees at which the (1-3)-th sub slit patterns SSLP1-3 and the (2-3)-th sub slit patterns SSLP2-3 rotate about the respective centers C1-3 and C2-3 may be different. For example, as described above, the (1-3)-th sub slit patterns SSLP1-3 and the (2-3)-th sub slit patterns SSLP2-3 may also have different positions.

According to this structure, since the light of the same wavelength may be radiated in different directions from each of the first pixel PXL1 and the second pixel PXL2, from the user's perspective, wavelengths of the light seen from the display panel PNL at a specific position may be different from each other, and thus a less diffraction pattern may be seen, thereby improving visibility of the user looking at the display panel PNL.

Next, referring to FIG. 9, the (1-1)-th to (1-3)-th sub slit patterns SSLP1-1, SSLP1-2, and SSLP1-3 may have the same elliptical shape as described above, and may have the same center C1-1, C1-2, and C1-3 in the (1-1)-th to (1-3)-th sub anode electrodes SAE1-1, SAE1-2, and SAE1-3 where the respective (1-1)-th to (1-3)-th sub slit patterns SSLP1-1, SSLP1-2, and SSLP1-3 may be positioned.

The (1-1)-th sub slit pattern SSLP1-1 and the (1-2)-th sub slit pattern SSLP1-2 may have substantially the same size, and the (1-3)-th sub slit pattern SSLP1-3 may have a size different from that of the (1-1)-th sub slit pattern SSLP1-1 and the (1-2)-th sub slit pattern SSLP1-2, but this is an example and is not necessarily limited thereto. According to an embodiment, the (1-3)-th sub slit pattern SSLP1-3 may have substantially the same size as the (1-1)-th sub slit pattern SSLP1-1 and the (1-2)-th sub slit pattern SSLP1-2.

All degrees at which the (1-1)-th to (1-3)-th sub slit patterns SSLP1-1, SSLP1-2, and SSLP1-3 rotate about the respective centers C1-1, C1-2, and C1-3 may be substantially the same. For example, since the respective centers C1-1, C1-2, and C1-3 and the degrees at which the (1-1)-th to (1-3)-th sub slit patterns SSLP1-1, SSLP1-2, and SSLP1-3 rotate about the respective centers C1-1, C1-2, and C1-3 may be substantially the same, the (1-1)-th to (1-3)-th sub slit patterns SSLP1-1, SSLP1-2, and SSLP1-3 may have substantially the same position.

Therefore, summarizing that described above, all of the (1-1)-th to (1-3)-th sub slit patterns SSLP1-1, SSLP1-2, and SSLP1-3 shown in FIG. 9 may be the first slit patterns SLP1 formed in the same pixel, for example, the first pixel PXL1, and may have substantially the same shape and position. Although the size of the (1-3)-th sub slit pattern SSLP1-3 may be different from the size of the (1-1)-th sub slit pattern SSLP1-1 and the (1-2)-th sub slit pattern SSLP1-2, this is only an example and may have substantially the same size.

Similarly, all of the (2-1)-th to (2-3)-th sub slit patterns SSLP2-1, SSLP2-2, and SSLP2-3 may also have the same elliptical shape as described above, and may have substantially the same center C2-1, C2-2, and C2-3 in the (2-1)-th to (2-3)-th sub anode electrodes SAE2-1, SAE2-2, and SAE2-3 where the respective (2-1)-th to (2-3)-th sub slit patterns SSLP2-1, SSLP2-2, and SSLP2-3 may be positioned.

The (2-1)-th sub slit pattern SSLP2-1 and the (2-2)-th sub slit pattern SSLP2-2 may have substantially the same size, and the (2-3)-th sub slit pattern SSLP2-3 may have a size different from that of the (2-1)-th sub slit pattern SSLP2-1 and the (2-2)-th sub slit pattern SSLP2-2, this is an example and is not necessarily limited thereto. According to an embodiment, the (2-3)-th sub slit pattern SSLP2-3 may have substantially the same size as the (2-1)-th sub slit pattern SSLP2-1 and the (2-2)-th sub slit pattern SSLP2-2.

All degrees at which the (2-1)-th to (2-3)-th sub slit patterns SSLP2-1, SSLP2-2, and SSLP2-3 rotate about the respective centers C2-1, C2-2, and C2-3 may be substantially the same. For example, since the respective centers C2-1, C2-2, and C2-3 and the degrees at which the (2-1)-th to (2-3)-th sub slit patterns SSLP2-1, SSLP2-2, and SSLP2-3 rotate about the respective centers C2-1, C2-2, and C2-3 may be substantially the same, the (2-1)-th to (2-3)-th sub slit patterns SSLP2-1, SSLP2-2, and SSLP2-3 may have substantially the same position as described above.

Therefore, summarizing that described above, all of the (2-1)-th to (2-3)-th sub slit patterns SSLP2-1, SSLP2-2, and SSLP2-3 may be the second slit patterns SLP2 formed in the same pixel, for example, the second pixel PXL2, and may have substantially the same shape and position. Although the size of the (2-3)-th sub slit pattern SSLP2-3 may be different from the size of the (2-1)-th sub slit pattern SSLP2-1 and the (2-2)-th sub slit pattern SSLP2-2, this is only an example and may have substantially the same size.

As described above, the slit pattern SLP may have the same shape, size, and position in a same pixel PXL, and this may be for setting the light characteristic implemented through a pixel PXL as consistently as possible.

The sub slit patterns formed in the sub-pixels of the same position in each of the first pixel PXL1 and the second pixel PXL2 adjacent to each other may have substantially the same shape and position, but sizes thereof may be different from each other.

Specifically, comparing the (1-1)-th sub slit pattern SSLP1-1 and the (2-1)-th sub slit pattern SSLP2-1 formed in the (1-1)-th sub-pixel SPXL1-1 and the (2-1)-th sub-pixel SPXL2-1 positioned at an upper left of the first pixel PXL1 and the second pixel PXL2, respectively, both of the (1-1)-th sub slit pattern SSLP1-1 and the (2-1)-th sub slit pattern SSLP2-1 may have substantially the same elliptical shape, and may have substantially the same size and substantially the same center C1-1 and C2-1 in the (1-1)-th sub anode electrode SAE1-1 and the (2-1)-th sub anode electrode SAE2-1, respectively.

However, the (1-1)-th sub slit pattern SSLP1-1 and the (2-1)-th sub slit pattern SSLP1-2 may have different sizes.

As described above, in this specification, since “size” is defined as the “total area” occupied by a specific component to which it refers, the size of the (1-1)-th sub slit pattern SSLP1-1 means the “total area” occupied by the (1-1)-th sub slit pattern SSLP1-1 in the (1-1)-th sub anode electrode SAE1-1, and the size of the (2-1)-th sub slit pattern SSLP2-1 similarly means the “total area” occupied by the (2-1)-th sub slit pattern SSLP2-1 in the (2-1)-th sub anode electrode SAE2-1.

In more detail, the total area occupied by the (1-1)-th sub slit pattern SSLP1-1 in the (1-1)-th sub anode electrode SAE1-1 may correspond to an area of a region except for a region surrounded by the innermost trench IT1-1 from a region surrounded by the outermost trench OT1-1.

Similarly, the total area occupied by the (2-1)-th sub slit pattern SSLP2-1 in the (2-1)-th sub anode electrode SAE2-1 may correspond to an area of a region except for a region surrounded by the innermost trench IT2-1 from a region surrounded by the outermost trench OT2-1.

Here, an area of a partial region A21 of the (2-1)-th sub slit pattern SSLP2-1 surrounded by the innermost trench IT2-1 of the (2-1)-th sub slit pattern SSLP2-1 may be less than an area of a partial region A11 of the (1-1)-th sub slit pattern SSLP1-1 surrounded by the innermost trench IT1-1 of the (1-1)-th sub slit pattern SSLP1-1 (for example, A11>A21).

Since a partial region of the (1-1)-th sub slit pattern SSLP1-1 surrounded by the outermost trench OT1-1 of the (1-1)-th sub slit pattern SSLP1-1 and a partial region of the (2-1)-th sub slit pattern SSLP2-1 surrounded by the outermost trench OT2-1 of the (2-1)-th sub slit pattern SSLP2-1 have substantially the same area (this is referred to as A0), it may be understood that an area of the (2-1)-th sub slit pattern SSLP2-1 may be greater than an area of the (1-1)-th sub slit pattern SSLP1-1 (because A0-A11<A0-A21).

For example, in conclusion, the (1-1)-th sub slit pattern SSLP1-1 and the (2-1)-th sub slit pattern SSLP2-1 may have different sizes.

Similarly, the total area occupied by the (1-2)-th sub slit pattern SSLP1-2 in the (1-2)-th sub anode electrode SAE1-2 may correspond to an area of a region except for a region surrounded by the innermost trench IT1-2 from a region surrounded by the outermost trench OT1-2.

Similarly to this, the total area occupied by the (2-2)-th sub slit pattern SSLP2-2 in the (2-2)-th sub anode electrode SAE2-2 may correspond to an area of a region except for a region surrounded by the innermost trench IT2-2 from a region surrounded by the outermost OT2-2.

Here, an area of a partial region A22 of the (2-2)-th sub slit pattern SSLP2-2 surrounded by the innermost trench IT2-2 of the (2-2)-th sub slit pattern SSLP2-2 may be less than an area of a partial region A12 of the (1-2)-th sub slit pattern SSLP1-2 surrounded by the innermost trench IT1-2 of the (1-2)-th sub slit pattern SSLP1-2 (for example, A12>A22).

Since a partial region of the (1-2)-th sub slit pattern SSLP1-2 surrounded by the outermost trench OT1-2 of the (1-2)-th sub slit pattern SSLP1-2 and a partial region of the (2-2)-th sub slit pattern SSLP2-2 surrounded by the outermost trench OT2-2 of the (2-2)-th sub slit pattern SSLP2-2 have substantially the same area (this is referred to as A0), it may be understood that an area of the (2-2)-th sub slit pattern SSLP2-2 may be greater than an area of the (1-2)-th sub slit pattern SSLP1-2 (because A0-A12<A0-A22).

For example, in conclusion, the (1-2)-th sub slit pattern SSLP1-2 and the (2-2)-th sub slit pattern SSLP2-2 may have different sizes.

The total area occupied by the (1-3)-th sub slit pattern SSLP1-3 in the (1-3)-th sub anode electrode SAE1-3 may correspond to an area A13 of a region except for a region surrounded by the innermost trench IT1-3 from a region surrounded by the outermost trench OT1-3.

Similarly, the total area occupied by the (2-3)-th sub slit pattern SSLP2-3 in the (2-3)-th sub anode electrode SAE2-3 may correspond to an area A23 of a region except for a region surrounded by the innermost trench IT2-3 from a region surrounded by the outermost trench OT2-3.

Here, an area of a partial region A23 of the (2-3)-th sub slit pattern SSLP2-3 surrounded by the innermost IT2-3 of the (2-3)-th sub slit pattern SSLP2-3 may be less than an area of a partial region A13 of the (1-3)-th sub slit pattern SSLP1-3 surrounded by the innermost trench IT1-3 of the (1-3)-th sub slit pattern SSLP1-3 (for example, A13>A23).

Since a partial region of the (1-3)-th sub slit pattern SSLP1-3 surrounded by the outermost trench OT1-3 of the (1-3)-th sub slit pattern SSLP1-3 and a partial region of the (2-3)-th sub slit pattern SSLP2-3 surrounded by the outermost trench OT2-3 of the (2-3)-th sub slit pattern SSLP2-3 have substantially the same area (this is referred to as A0), it may be understood that an area of the (2-3)-th sub slit pattern SSLP2-3 may be greater than an area of the (1-3)-th sub slit pattern SSLP1-3 (because A0-A13<A0-A23).

For example, in conclusion, the (1-3)-th sub slit pattern SSLP1-3 and the (2-3)-th sub slit pattern SSLP2-3 may have different sizes.

According to the structure described above, since the light of the same wavelength may be radiated in different directions from each of the first pixel PXL1 and the second pixel PXL2, from the user's perspective, wavelengths of the light seen from the display panel PNL at a specific position may be different from each other, and thus a less diffraction pattern may be seen, thereby improving visibility of the user looking at the display panel PNL.

Hereinafter, a method of manufacturing the display device according to the embodiments of the disclosure described above is described with reference to FIGS. 10 to 21A.

FIG. 10 is a schematic cross-sectional view illustrating forming the pixel circuit layer on the substrate.

Referring to FIG. 10, the pixel circuit layer PCL may be formed on the substrate SUB. As described in detail above, the pixel circuit layer PCL may include insulating layers, semiconductor patterns formed between the insulating layers, and conductive patterns that function as a circuit element, a line, and the like. The pixel circuit layer PCL may be formed through a process such as deposition, patterning, and an etching process according to a processing characteristic of each component.

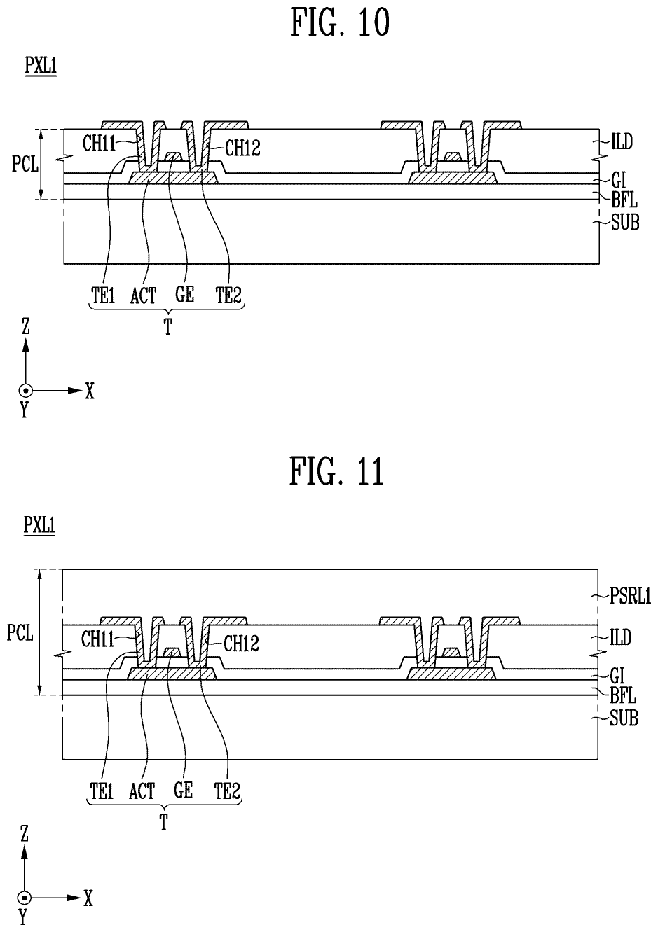

FIG. 11 is a schematic cross-sectional view illustrating forming a first photosensitive material layer on the pixel circuit layer.

Referring to FIG. 11, a photosensitive material may be applied to the entire surface of the pixel circuit layer PCL including the transistor T to form a first photosensitive material layer PSRL1. As the photosensitive material, for example, a photodegradable polymer resin may be used. As such a photodegradable polymer resin, an organic material which may be a material of the above-describe via layer VIA may be used.

Although not shown, before forming the first photosensitive material layer PSRL1 on the pixel circuit layer, the passivation layer PSV may be first formed by selecting at least one of the materials of the above-described passivation layer PSV.

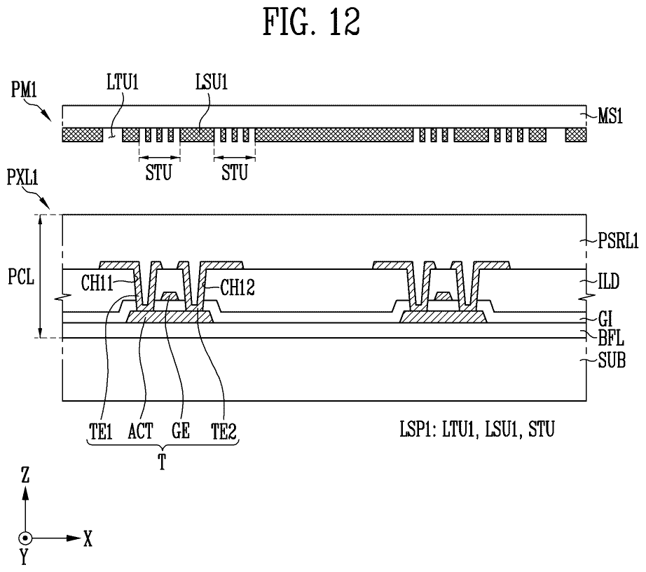

FIG. 12 is a schematic cross-sectional view illustrating a state in which a first pattern mask may be disposed on the first photosensitive material layer.

Referring to FIG. 12, the first pattern mask PM1 may be spaced apart from the first photosensitive material layer PSRL1 and may be disposed on the first photosensitive material layer PSRL1. The first pattern mask PM1 may include a first mask substrate MS1 and a first light blocking pattern LSP1 disposed on the first mask substrate MS1. The first light blocking pattern LSP1 may include at least three areas having different light transmittances. The first pattern mask PM1 may also be referred to as a half tone mask.

A transparent glass or plastic substrate may be used as the first mask substrate MS1, but is not necessarily limited thereto. According to an embodiment, the first mask substrate MS1 may be manufactured with another material having light transparency and a mechanical strength (e.g., predetermined or selectable mechanical strength).

The first light blocking pattern LSP1 may be manufactured by selectively applying a light blocking material to the first mask substrate MS1. The first light blocking pattern LSP1 may include a first light transmitting portion LTU1, a first light blocking portion LSU1, and a semi-transmissive portion STU.

The first light transmitting portion LTU1 may be an area through which light passes through, and may be positioned on an area where the contact hole CH2 may be formed in the via layer VIA.

The first light blocking portion LSU1 may be a portion that blocks transmission of light, and may be formed by applying a light blocking material to the first mask substrate MS1.

The semi-transmissive portion STU may be a portion through which a portion of incident light passes through, and may be positioned on an area where the slit patterns SLP may be formed. For example, the semi-transmissive portion STU may have a structure in which a light transmission hole LTH and a light blocking bar LSB may be alternately disposed. At this time, light transmittance of the semi-transmissive portion STU may be adjusted by adjusting the number or a width of the light transmission hole LTH, and through this, a width and a depth of the slit pattern SLP may be adjusted. As another example, the light transmittance of the semi-transmissive portion STU may also be adjusted by adjusting a concentration of the light blocking material.

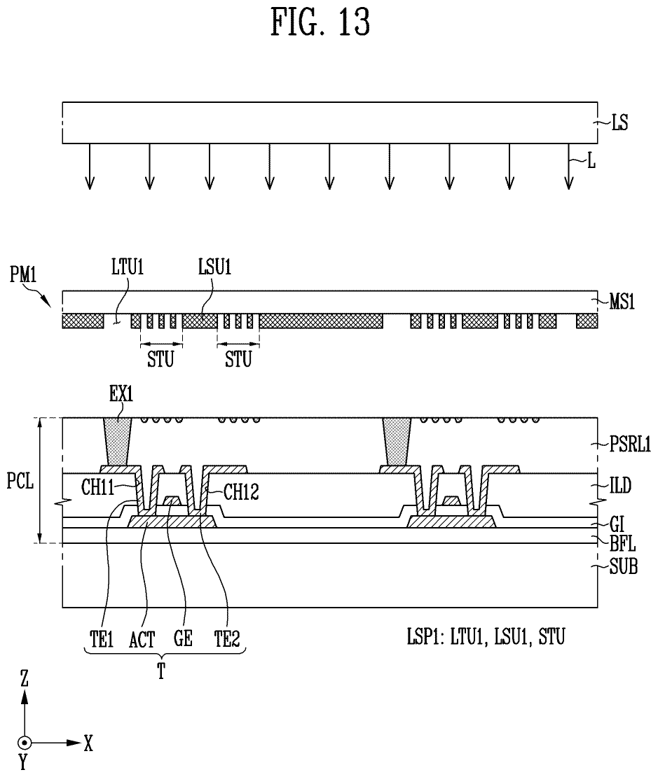

FIG. 13 is a schematic cross-sectional view illustrating irradiating light toward the first pattern mask and the first photosensitive material layer.

Referring to FIG. 13, light L may be irradiated from a light source LS in the Z-axis direction in a state in which the first pattern mask PM1 may be disposed on the first photosensitive material layer PSRL1. A remaining area EX1 except for a partial area of the first photosensitive material layer PSRL1 covered by the first light blocking portion LSU1 may be exposed to light, and thus a chemical property may change.

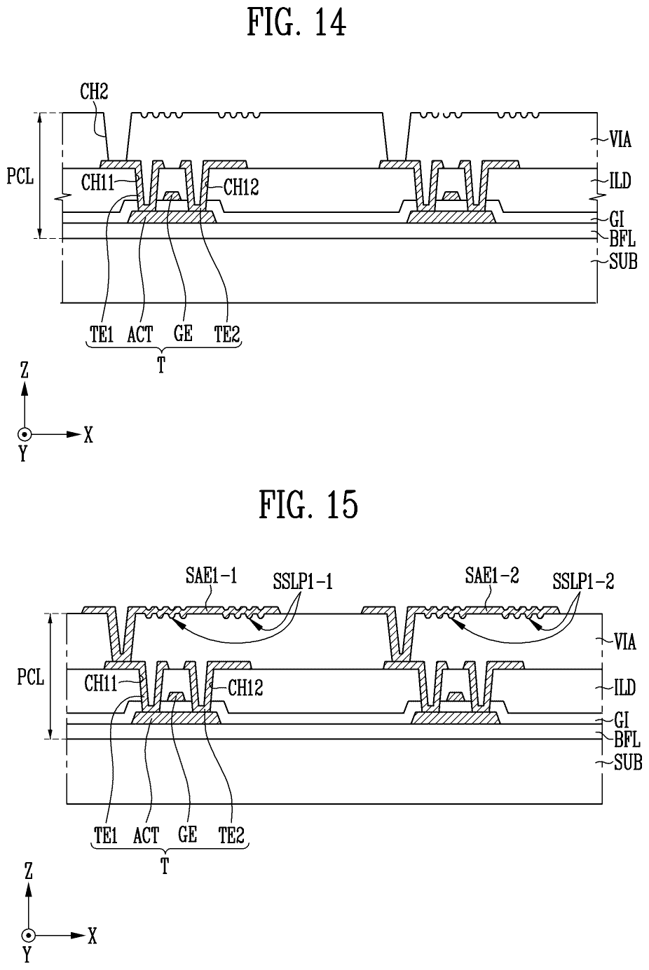

FIG. 14 is a schematic cross-sectional view illustrating developing a partial area of the exposed first photosensitive material layer.

Referring to FIG. 14, a partial area of the first photosensitive material layer PSRL1 of which a chemical property changes due to exposure to light may be removed by an etchant, and thus the slit patterns SLP and the via layer VIA including the contact holes CH2 may be formed. As described above, the first photosensitive material layer PSRL1 which has a characteristic of dissolving the exposed area by the etchant is referred to a positive photoresist, and conversely, the first photosensitive material layer PSRL1 which has a characteristic of dissolving an unexposed area by the etchant is referred to a negative photoresist.

FIG. 15 is a schematic cross-sectional view illustrating forming the anode electrode on the via layer.

Referring to FIG. 15, multiple anode electrodes AE may be formed on the via layer VIA. The anode electrodes AE may be electrically connected to the first transistor electrodes TE1 of the pixel circuit layer PCL through the contact hole CH2, respectively.

A portion of the anode electrodes AE that overlaps the respective slit patterns SLP may have a shape corresponding to the corresponding slit pattern SLP. According to embodiments, the (1-1)-th sub anode electrode SAE1-1 overlapping the (1-1)-th sub slit pattern SSLP1-1 may correspond to a cross-sectional shape of the (1-1)-th sub slit pattern SSLP1-1, and the (1-2)-th sub anode electrode SAE1-2 and the (1-3)-th sub anode electrode SAE1-3 also may have a cross-sectional shape of the (1-2)-th sub slit pattern SSLP1-2 and the (1-3)-th sub slit pattern SSLP1-3, respectively, similarly to the (1-1)-th sub anode electrode SAE1-1.

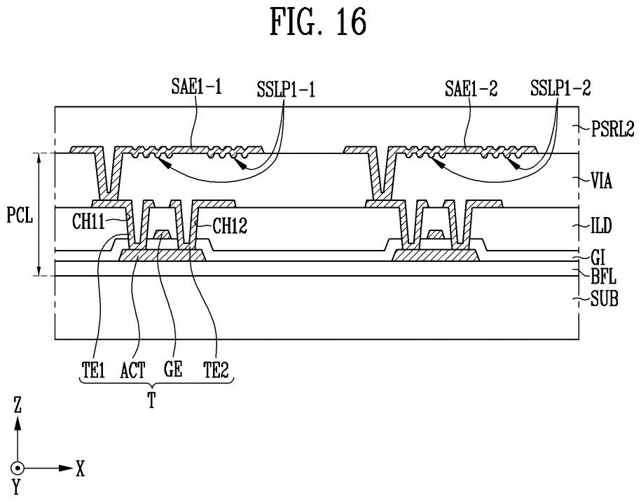

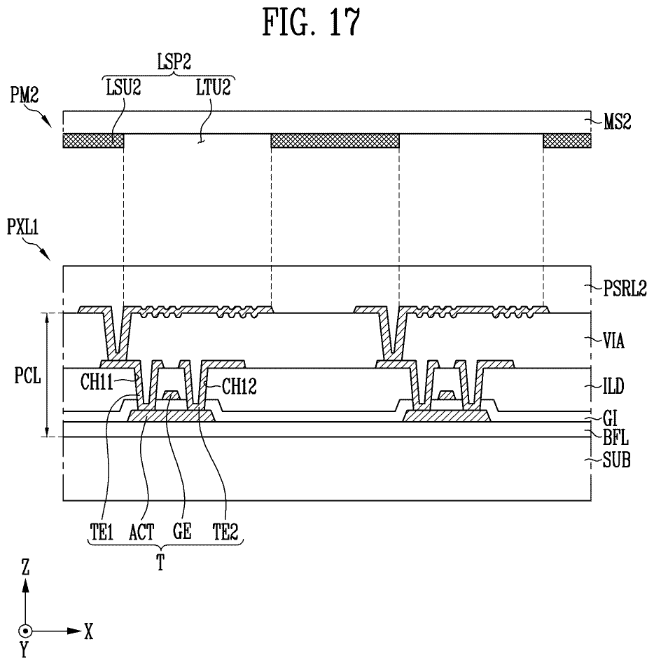

FIG. 16 is a schematic cross-sectional view illustrating forming a second photosensitive material layer on the via layer and the anode electrode.

Referring to FIG. 16, a photosensitive material may be applied to an upper surface of the via layer VIA and the anode electrode AE to form a second photosensitive material layer PSRL2. Similarly to the first photosensitive material layer PSRL1, a photodegradable polymer resin may be used as the photosensitive material.

FIG. 17 is a schematic cross-sectional view illustrating a state in which a second pattern mask may be disposed on the second photosensitive material layer.

Referring to FIG. 17, the second pattern mask PM2 may be spaced apart from the second photosensitive material layer PSRL2 and may be disposed on the second photosensitive material layer PSRL2. Similarly to the first pattern mask PM1, the second pattern mask PM2 may also include a second mask substrate MS1 and a second light blocking pattern LSP2 disposed on the second mask substrate MS1.

As the second mask substrate MS2 of the second pattern mask PM2, a transparent glass or a plastic substrate may be used, but is not necessarily limited thereto. According to an embodiment, the second mask substrate MS2 may be manufactured with another material having light transparency and a mechanical strength (e.g., predetermined or selectable mechanical strength).

The second light blocking pattern LSP2 may be manufactured by selectively applying alight blocking material to the second mask substrate MS. The second light blocking pattern LSP2 may include a second light transmitting portion LTU2 and a second light blocking portion LSU2.

The second light transmitting portion LTU2 may be an area through which light passes through and may be positioned on an area where the opening OP may be formed.

The second light blocking portion LSU2 may be a portion that blocks transmission of light and may be positioned on an area where the opening OP may not be formed.

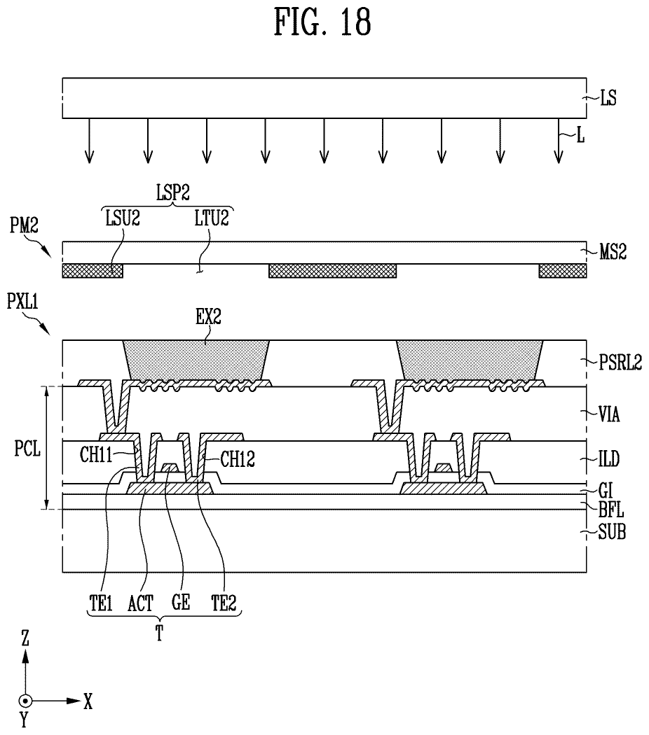

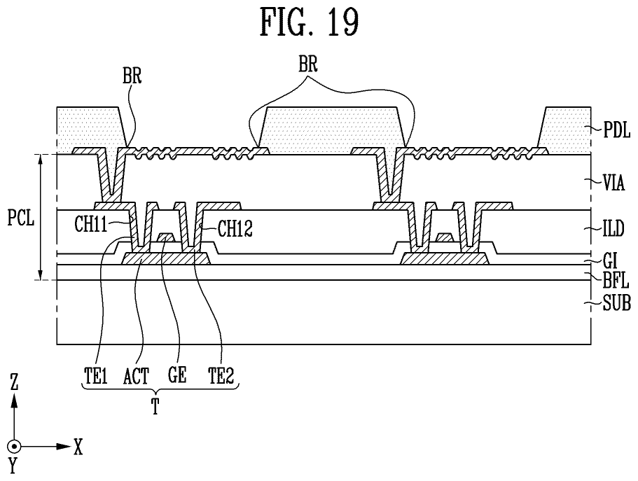

FIG. 18 is a schematic cross-sectional view irradiating light toward the second pattern mask and the second photosensitive material layer.

Referring to FIG. 18, light may be irradiated in the Z-axis direction in a state in which the second pattern mask PM2 may be disposed on the second photosensitive material layer PSRL2. A remaining area EX2 except for a partial area of the second photosensitive material layer PSRL2 covered by the second light blocking portion LSU2 may be exposed to light, and thus a chemical property may change.

FIG. 19 is a schematic cross-sectional view illustrating forming the pixel defining layer by developing a partial region of the exposed second photosensitive material layer.

Referring to FIG. 19, a partial region of the second photosensitive material layer PSRL2 of which a chemical property changes due to exposure to light may be removed by an etchant, and thus an upper surface of the anode electrodes AE may be exposed.

A thermal curing process may be performed on a partial area of the second photosensitive material layer PSRL2 which may not be removed by the etchant, and thus the pixel defining layer PDL may be formed.

The opening OP and an edge BR of the opening OP may be defined by the pixel defining layer PDL. The anode electrode AE may be exposed from the pixel defining layer PDL by the opening OP. The pixel defining layer PDL may expose an upper surface of the anode electrode AE and may protrude in a circumference of the anode electrode AE. The pixel defining layer PDL may partially overlap an end of the anode electrode AE, and the opening OP may be positioned on the anode electrode AE. The pixel defining layer PDL may be disposed on the anode electrode AE to planarize an empty space between the anode electrodes AE.

The edge BR of the opening OP may not overlap the slit pattern SLP. For example, the edge BR of the opening OP may be formed spaced apart from the slit pattern SLP at a distance (e.g., predetermined or selectable distance).

In case that a pattern is formed by photolithography, forming a uniform pattern is difficult in case that a bottom surface of a boundary area of the pattern is not approximately flat. According to embodiments of the disclosure, since the slit pattern SLP may not be formed on the edge BR of the opening OP, the edge BR of the opening OP may be positioned on an approximately flat plane. Accordingly, a pattern defect may be prevented from occurring in a formation process of the pixel defining layer PDL.

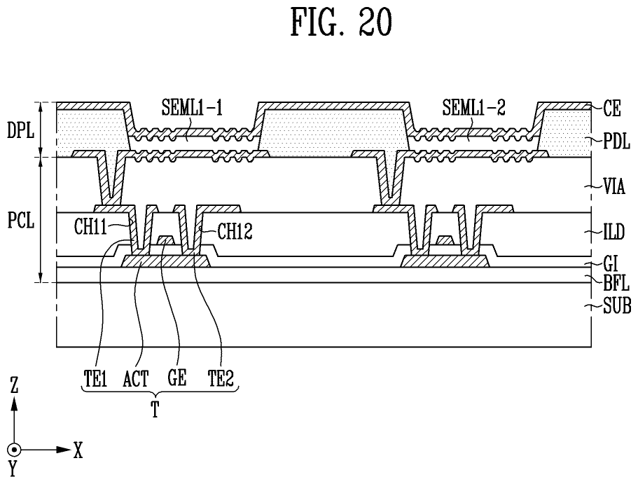

FIG. 20 is a schematic cross-sectional view illustrating forming the light emitting element layer and the cathode electrode on the anode electrode exposed by the opening.

Referring to FIG. 20, the sub light emitting element layer SEML1-1 and the cathode electrode CE may be formed sequentially on an upper surface of the anode electrode SAE1-1 exposed by the opening OP. The cathode electrode CE may also be formed on the pixel defining layer PDL.

The sub light emitting element layer SEML1-1 and the cathode electrode CE may be preferably formed by vapor deposition, but are not necessarily limited thereto. According to an embodiment, the sub light emitting element layer SEML1-1 and the cathode electrode CE may be formed in a suitable method according to each material.

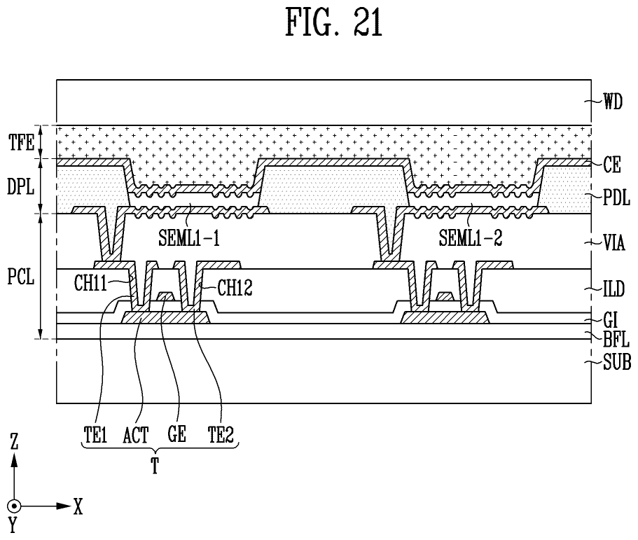

FIG. 21 is a schematic cross-sectional view illustrating forming the thin film encapsulation layer and the window on the cathode electrode.

Referring to FIG. 21, the thin film encapsulation layer TFE may be formed on the cathode electrode CE. As described above, the thin film encapsulation layer TFE may have a structure in which an organic layer with excellent planarization and shock absorption functions and an inorganic layer with an excellent function of blocking an external substance such as moisture or air may be alternately stacked on each other.

The window WD may be disposed on the thin film encapsulation layer TFE. The window WD may protect lower members from external shock and provide an input surface and/or a display surface to the user. Specifically, the window WD may have a multiple layer structure selected from a glass substrate, a plastic film, and a plastic substrate, and the multiple layer structure may be formed through a continuous process and an adhesion process using an adhesive layer. The entire window WD may have flexibility.

Although not shown for convenience of description, a sensing layer (not shown), a light blocking layer (not shown), and a color filter layer (not shown) may be interposed between the window WD and the thin film encapsulation layer TFE, but are not necessarily limited thereto. According to embodiments, at least one of the sensing layer, the light blocking layer, and the color filter layer may be omitted.

Although specific embodiments and applications are described herein, other embodiments and variations may be derived from the above description. Therefore, the spirit of the disclosure is not limited to these embodiments, and extends to the scope of the claims set forth below, various obvious modifications, and equivalents.

What is claimed is:

1. A display device, comprising:
a first pixel adjacent to a second pixel;
a pixel circuit layer disposed on a substrate; and
a display element layer including a plurality of anode electrodes disposed on the pixel circuit layer, wherein the plurality of anode electrodes include a first anode electrode corresponding to the first pixel and a second anode electrode corresponding to the second pixel, wherein
the pixel circuit layer includes a via layer facing the display element layer,
an upper surface of the via layer includes a plurality of slit patterns respectively overlapping the plurality of anode electrodes, and the plurality of slit patterns are adjacent to the display element layer,
the plurality of slit patterns include a first slit pattern overlapping the first anode electrode and a second slit pattern overlapping the second anode electrode, and the first slit pattern and the second slit pattern are different from each other in at least one of a shape, a size, and a position, and
a portion of the first and second anode electrodes overlapping the first and second slit patterns has a shape corresponding to the first and second slit patterns.

2. The display device according to claim 1, wherein
the first pixel includes a (1-1)-th sub-pixel and a (1-2)-th sub-pixel adjacent to the (1-1)-th sub-pixel,
the second pixel includes a (2-1)-th sub-pixel and a (2-2)-th sub-pixel adjacent to the (2-1)-th sub-pixel,
the first anode electrode includes a (1-1)-th sub anode electrode corresponding to the (1-1)-th sub-pixel and a (1-2)-th sub anode electrode corresponding to the (1-2)-th sub-pixel,
the second anode electrode includes a (2-1)-th sub anode electrode corresponding to the (2-1)-th sub-pixel and a (2-2)-th sub anode electrode corresponding to the (2-2)-th sub-pixel,
the first slit pattern includes a (1-1)-th sub slit pattern corresponding to the (1-1)-th sub anode electrode and a (1-2)-th sub slit pattern corresponding to the (1-2)-th sub anode electrode, and the (1-1)-th sub slit pattern and the (1-2)-th sub slit pattern have substantially a same shape, and
the second slit pattern includes a (2-1)-th sub slit pattern corresponding to the (2-1)-th sub anode electrode and a (2-2)-th sub slit pattern corresponding to the (2-2)-th sub anode electrode, and the (2-1)-th sub slit pattern and the (2-2)-th sub slit pattern have substantially a same shape.

3. The display device according to claim 2, wherein the (1-1)-th sub slit pattern and the (1-2)-th sub slit pattern have different sizes.

4. The display device according to claim 3, wherein the (2-1)-th sub slit pattern and the (2-2)-th sub slit pattern have different sizes.

5. The display device according to claim 1, wherein the first slit pattern and the second slit pattern have an elliptical shape.

6. The display device according to claim 5, wherein a first center of the first slit pattern in the first pixel and a second center of the second slit pattern in the second pixel are disposed at substantially a same position.

7. The display device according to claim 6, wherein
the first slit pattern includes a (1-1)-th trench and a (1-2)-th trench of a closed loop shape which are sequentially formed spaced apart from each other in a radial direction with respect to the first center, and
the second slit pattern includes a (2-1)-th trench and a (2-2)-th trench of a closed loop shape which are sequentially formed spaced apart from each other in a radial direction with respect to the second center.

8. The display device according to claim 7, wherein an area of a portion of the first slit pattern surrounded by the (1-1)-th trench is different from an area of a portion of the second slit pattern surrounded by the (2-1)-th trench.

9. The display device according to claim 7, wherein
each of the (1-1)-th trench and the (1-2)-th trench has a width of about 1.5 μm or less in the radial direction with respect to the first center, and
each of the (2-1)-th trench and the (2-2)-th trench has a width of about 1.5 μm or less in the radial direction with respect to the second center.

10. The display device according to claim 7, wherein
the (1-1)-th trench and the (1-2)-th trench are spaced apart from each other by a distance of about 1.5 μm or less in the radial direction with respect to the first center, and
the (2-1)-th trench and the (2-2)-th trench are spaced apart from each other by a distance of about 1.5 μm or less in the radial direction with respect to the second center.

11. The display device according to claim 7, wherein
a farthest separation distance between the first center and the (1-1)-th trench is defined as a first major radius,
a farthest separation distance between the second center and the (2-1)-th trench is defined as a second major radius, and
a virtual line extending in the first major radius and a virtual line extending in the second major radius intersect each other.

12. The display device according to claim 11, wherein
a closest separation distance between the first center and the (1-1)-th trench is defined as a first minor radius,
a closest separation distance between the second center and the (2-1)-th trench is defined as a second minor radius,
the first major radius and the first minor radius are determined according to Formula 1,
the second major radius and the second minor radius are determined according to Formula 2, and
$${( 1 - {( RB 1 )}^{2} / {( RA 1 )}^{2} )}^{1 / 2} \leq 0.7 \qquad [ Formula 1 ]$$
$${( 1 - {( RB 2 )}^{2} / {( RA 2 )}^{2} )}^{1 / 2} \leq 0.7 \qquad [ Formula 2 ]$$
the RA1, RB1, RA2, and RB2 represent the first major radius, the first minor radius, the second major radius, and the second minor radius, respectively.

13. The display device according to claim 2, wherein
the first pixel further includes a (1-3)-th sub-pixel adjacent to the (1-1)-th sub-pixel and the (1-2)-th sub-pixel,
the second pixel further includes a (2-3)-th sub-pixel adjacent to the (2-1)-th sub-pixel and the (2-2)-th sub-pixel,
the first anode electrode further includes a plurality of (1-3)-th sub anode electrodes corresponding to the (1-3)-th sub-pixel,
the second anode electrode further includes a plurality of (2-3)-th sub anode electrodes corresponding to the (2-3)-th sub-pixel,
the first slit pattern further includes a plurality of (1-3)-th sub slit patterns overlapping the (1-3)-th sub anode electrode, and
the second slit pattern further includes a plurality of (2-3)-th sub slit patterns overlapping the (2-3)-th sub anode electrode.

14. The display device according to claim 13, wherein a position in the (1-3)-th sub-pixel of at least one of first centers of the plurality of (1-3)-th sub slit patterns in the plurality of (1-3)-th sub anodes is different from a position in the (2-3)-th sub-pixel of at least one of second centers of the plurality of (2-3)-th sub slit patterns in the plurality of (2-3)-th sub anodes.

15. The display device according to claim 13, wherein at least one of the (1-1)-th sub slit pattern, the (1-2)-th sub slit pattern, and the (1-3)-th sub slit pattern has a size different from another of the (1-1)-th sub slit pattern, the (1-2)-th sub slit pattern, and the (1-3)-th sub slit pattern.

16. The display device according to claim 13, wherein at least one of the (2-1)-th sub slit pattern, the (2-2)-th sub slit pattern, and the (2-3)-th sub slit pattern has a size different from another of the (2-1)-th sub slit pattern, the (2-2)-th sub slit pattern, and the (2-3)-th sub slit pattern.

17. A method of manufacturing a display device, the method comprising:
providing a first pixel adjacent to a second pixel;
forming a pixel circuit layer on a substrate;
forming a via layer on the pixel circuit layer, the via layer including a first portion corresponding to the first pixel and a second portion corresponding to a second pixel;
forming a plurality of slit patterns in the via layer, the plurality of slit patterns including a first slit pattern corresponding to the first portion of the via layer and the second portion corresponding to the second portion of the via layer; and
forming a plurality of anode electrodes including a first anode electrode overlapping the first slit pattern and a second anode electrode overlapping the second slit pattern, wherein
the first slit pattern and the second slit pattern are different in at least one of a shape, a size, and a position.

18. The method according to claim 17, wherein the forming of the plurality of slit patterns comprises:
irradiating light to the first and second portions of the via layer using a mask where an opening corresponding to a shape of the first slit pattern and the second slit pattern is formed; and
forming the first slit pattern and the second slit pattern through exposure and development processes.

19. The method according to claim 17, wherein
each of the first slit pattern and the second slit pattern is formed in an elliptical shape, and
positions of the first slit pattern and the second slit pattern are different from each other.

20. The method according to claim 17, wherein a portion of the first and second anode electrodes overlapping the first and second slit patterns has a shape corresponding to the first and second slit patterns.
